(19) United States
(12) Patent Application Publication
(10) Pub. No.: US 2024/0407184 A1
(43) Pub. Date: Dec. 5, 2024

(54) LIGHT DETECTION DEVICE, METHOD OF MANUFACTURING THE SAME, ELECTRONIC EQUIPMENT, AND MOBILE BODY

(71) Applicant: SONY SEMICONDUCTOR SOLUTIONS CORPORATION, KANAGAWA (JP)

(72) Inventors: KENICHI MURATA, KANAGAWA (JP); KOTARO NISHIMURA, KANAGAWA (JP); IWAO YAGI, KANAGAWA (JP); MASAHIRO JOEI, KANAGAWA (JP); TOSHIHIKO HAYASHI, KANAGAWA (JP); HIROYASU MATSUGAI, KANAGAWA (JP)

(21) Appl. No.: 18/701,247

(22) PCT Filed: Sep. 20, 2022
(86) PCT No.: PCT/JP2022/034945

§ 371 Date: Apr. 14, 2024

(30) Foreign Application Priority Data
Oct. 20, 2021 (JP) 2021-171955

(51) Int. Cl. H10K 39/32; G02B 5/20

(52) U.S. Cl. CPC H10K 39/32; G02B 5/201

(57) ABSTRACT

Provided is a light detection device having high reliability. The light detection device includes arrays of multiple pixels, and partition walls. The multiple pixels each include a color filter, a first photoelectric conversion unit, and an oxide semiconductor. The first photoelectric conversion unit detects light in the first wavelength range having transmitted through the color filter, performs photoelectric conversion, and generates an electric charge. The oxide semiconductor is configured to store the electric charge. The partition wall is located in a gap between the color filters of the multiple pixels, and has a refractive index lower than that of the color filter.

### TECHNICAL FIELD

The present disclosure relates to a light detection device, electronic equipment, and a mobile body each of which includes a photoelectric converter that performs photoelectric conversion, and a method of manufacturing the light detection device.

### BACKGROUND ART

A solid-state imaging apparatus has been proposed that has a stacked structure including a first photoelectric conversion region that mainly receives visible light and performs photoelectric conversion, and a second photoelectric conversion region that mainly receives infrared light and performs photoelectric conversion (refer to PTL 1, for example).

### CITATION LIST

### Patent Literature

PTL 1: Japanese Unexamined Patent Application Publication No. 2017-208496

### SUMMARY OF INVENTION

Meanwhile, there has been a demand for an improvement in reliability of a solid-state imaging apparatus.

Therefore, it is desirable to provide a light detection device having high reliability.

A light detection device according to an embodiment of the present disclosure includes arrays of multiple pixels and a partition wall. The multiple pixels each includes a color filter, a first photoelectric conversion layer, and an oxide semiconductor. The first photoelectric conversion layer detects light in a first wavelength range having transmitted through the color filter and performs photoelectric conversion to generate an electric charge. The oxide semiconductor is configured to store the electric charge. The partition wall is located in a gap between the color filters of the multiple pixels, and has a refractive index lower than that of the color filter.

According to the light detection device of the embodiment of the present disclosure, the partition wall has a refractive index lower than that of the color filter. It is therefore possible to prevent light incident on the color filter from leaking from the color filter to the surroundings.

### BRIEF DESCRIPTION OF DRAWINGS

FIG. 1A is a schematic configuration diagram illustrating an example of a solid-state imaging apparatus according to an embodiment of the present disclosure.

FIG. 1B is an explanatory diagram schematically illustrating a configuration example of a pixel unit illustrated in FIG. 1A and a peripheral unit around the pixel unit.

FIG. 2A is a vertical cross-sectional view of a schematic configuration example of an imaging element to be applied to the pixel unit illustrated in FIG. 1A.

FIG. 2B is a horizontal cross-sectional view of the schematic configuration example of the imaging element to be applied to the pixel unit illustrated in FIG. 1A.

FIG. 2C is another horizontal cross-sectional view of the schematic configuration example of the imaging element to be applied to the pixel unit illustrated in FIG. 1A.

FIG. 3A is an enlarged vertical cross-sectional view of a main portion of the imaging element illustrated in FIG. 2A.

FIG. 3B is another enlarged vertical cross-sectional view of the main portion of the imaging element illustrated in FIG. 2A.

FIG. 3C is a vertical cross-sectional view of a schematic configuration example of the peripheral unit illustrated in FIG. 1B.

FIG. 3D is an enlarged horizontal cross-sectional view of a portion of the peripheral unit illustrated in FIG. 3C.

FIG. 4A is an enlarged schematic cross-sectional view of a through-electrode and a peripheral unit around the through-electrode illustrated in FIG. 2A.

FIG. 4B is an enlarged schematic plan view of the through-electrode and the periphery of the through-electrode illustrated in FIG. 2A.

FIG. 5 is a circuit diagram illustrating an example of a readout circuit of an iTOF sensor illustrated in FIG. 2A.

FIG. 6 is a circuit diagram illustrating an example of a readout circuit of an organic photoelectric conversion unit illustrated in FIG. 2A.

FIG. 7A is a vertical cross-sectional view of a schematic configuration example of a solid-state imaging apparatus according to a first modification example of a first embodiment of the present disclosure.

FIG. 7B is a vertical cross-sectional view of a schematic configuration example of a solid-state imaging apparatus according to a second modification example of the first embodiment of the present disclosure.

FIG. 7C is a first vertical cross-sectional view of a schematic configuration example of a solid-state imaging apparatus according to a third modification example of the first embodiment of the present disclosure.

FIG. 7D is a second vertical cross-sectional view of the schematic configuration example of the solid-state imaging apparatus according to the third modification example of the first embodiment of the present disclosure.

FIG. 8A is a schematic diagram illustrating an overall configuration example of a light detection system according to a third embodiment of the present disclosure.

FIG. 8B is a schematic diagram illustrating a circuit configuration example of the light detection system illustrated in FIG. 8A.

FIG. 9 is a schematic diagram illustrating an overall configuration example of electronic equipment.

FIG. 10 is a block diagram depicting an example of a schematic configuration of an in-vivo information acquisition system.

FIG. 11 is a view depicting an example of a schematic configuration of an endoscopic surgery system.

FIG. 12 is a block diagram depicting an example of a functional configuration of a camera head and a camera control unit (CCU).

FIG. 13 is a block diagram depicting an example of schematic configuration of a vehicle control system.

FIG. 14 is a diagram of assistance in explaining an example of installation positions of an outside-vehicle information detecting section and an imaging section.

FIG. 15 is an explanatory diagram schematically illustrating the pixel unit and a peripheral unit around the pixel unit illustrated in FIG. 1A

### MODES FOR CARRYING OUT THE INVENTION

In the following, embodiments of the present disclosure are described in detail with reference to the accompanying drawings. It is to be noted that the description will be given in the following order.

### 1. First Embodiment

An example of a solid-state imaging apparatus in which a partition wall including a LTO having a refractive index lower than that of a color filter is disposed in a gap between color filters of multiple pixels.

### 2. Second Embodiment

An example of a solid-state imaging apparatus in which a partition wall including a sputtering film is disposed in a gap between color filters of multiple pixels.

### 3. Third Embodiment

An example of a light detection system including a light emitting device and a light detection device.

### 4. Exemplary Application to Electronic Equipment

### 5. Application Example to In-vivo Information Acquisition System

### 6. Application Example to Endoscopic Surgery System

### 7. Exemplary Application to Mobile Body

### 8. Other Modification Examples

### 1. First Embodiment

### [Configuration of Solid-state Imaging Apparatus 1]

### (Overall Configuration Example)

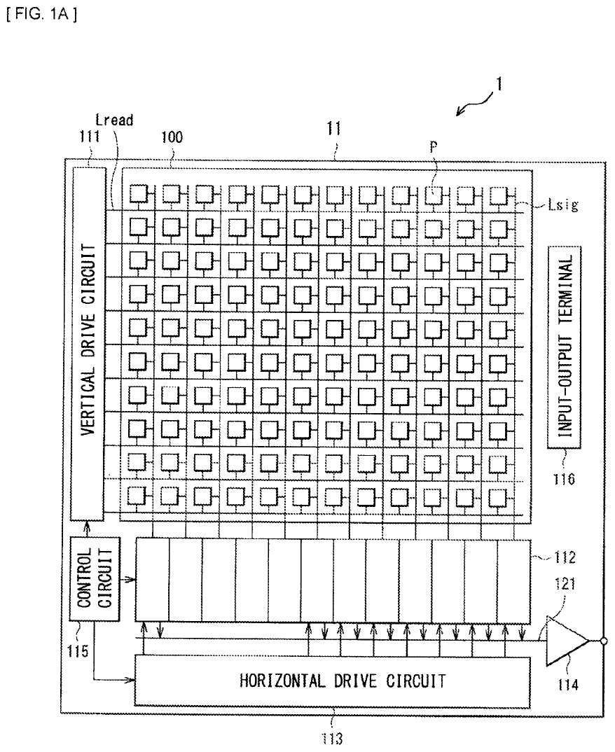

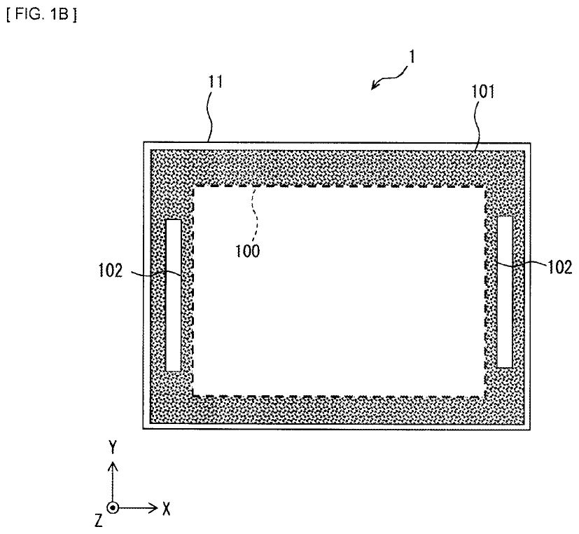

FIG. 1A is a diagram illustrating an overall configuration example of a solid-state imaging apparatus 1 according to a first embodiment of the present disclosure. FIG. 1B is an enlarged schematic diagram illustrating a pixel unit 100 and a periphery of the pixel unit 100 of the solid-state imaging apparatus 1. The solid-state imaging apparatus 1 is, for example, a complementary metal oxide semiconductor (CMOS) image sensor. The solid-state imaging apparatus 1 takes in incident light (image light) from a subject through, for example, an optical lens system, converts the incident light formed on an imaging surface into an electric signal on a pixel unit basis, and outputs the electric signal as a pixel signal. The solid-state imaging apparatus 1 includes, for example, the pixel unit 100 serving as an effective region, and a peripheral unit 101 serving as a peripheral region adjacent to the pixel unit 100 on a semiconductor substrate 11. The peripheral unit 101 is provided so as to surround the pixel unit 100, for example. The peripheral unit 101 is provided with, for example, a vertical drive circuit 111, a column signal processing circuit 112, a horizontal drive circuit 113, an output circuit 114, a control circuit 115, and an input-output terminal 116.

It is to be noted that the solid-state imaging apparatus 1 is a specific example corresponding to a “light detection device” of the present disclosure.

As illustrated in FIG. 1A, the pixel unit 100 includes multiple pixels P arranged in two-dimensional matrix, for example. In a portion of the peripheral unit 101, a contact region 102 is provided to which a contact layer 57 (to be described later) and a lead-out wire 58 (to be described later) are coupled. The pixel unit 100 includes, for example, multiple pixel rows each including multiple pixels P arranged in a horizontal direction (a lateral direction of the page) and multiple of pixel columns each including multiple pixels P arranged in a vertical direction (a longitudinal direction of the page). In the pixel unit 100, for example, one pixel drive line Lread (a row selection line and a reset control line) is provided for each pixel row, and one vertical signal line Lsig is provided for each pixel column. The pixel drive line Lread transmits driving signals to read a signal from each pixel P. Ends of the multiple pixel drive lines Lread are coupled to multiple output terminals corresponding to the respective pixel rows of the vertical drive circuit 111.

The vertical drive circuit 111 is configured by a shift register, an address decoder, or the like. The vertical drive circuit 111 is a pixel drive unit that drives each pixel P in the pixel unit 100 on a pixel-row unit basis, for example. A signal outputted from each pixel P of a pixel row selectively scanned by the vertical drive circuit 111 is supplied to the column signal processing circuit 112 via a corresponding vertical signal lines Lsig.

The column signal processing circuit 112 is configured by an amplifier, a horizontal selection switch, and the like provided for each vertical signal line Lsig.

The horizontal drive circuit 113 is configured by a shift register, an address decoder, and the like. The horizontal drive circuit 113 drives the horizontal selection switches of the column signal processing circuit 112 in sequence while scanning the horizontal selection switches. As a result of the selective scanning by the horizontal drive circuit 113, the signals of the respective pixels P transmitted through the respective vertical signal lines Lsig are sequentially outputted to the horizontal signal line 121, and transmitted to the outside of the semiconductor substrate 11 through the horizontal signal line 121.

The output circuit 114 performs signal processing on the signals sequentially supplied from the column signal processing circuits 112 via the horizontal signal line 121, and outputs the processed signals. For example, the output circuit 114 performs only buffering in some cases, and performs a black level adjustment, column variation correction, and a variety of digital signal processing in other cases.

A circuit portion including the vertical drive circuit 111, the column signal processing circuits 112, the horizontal drive circuit 113, the horizontal signal line 121, and the output circuit 114 may be formed directly on the semiconductor substrate 11 or may be provided on an external control IC. Alternatively, the circuit portion may be formed on another substrate coupled with a cable, for example.

The control circuit 115 receives, for example, a clock or data on a command for an operation mode supplied from the outside of the semiconductor substrate 11, and outputs data such as internal information on the pixels P that are imaging elements. The control circuit 115 further includes a timing generator that generates various timing signals. On the basis of the various timing signals generated by the timing generator, the control circuit 115 controls driving of peripheral circuitry including the vertical drive circuit 111, the column signal processing circuit 112, and the horizontal drive circuit 113.

The input-output terminal 116 exchanges signals with an external device.

### (Exemplary Cross-sectional Configuration of Pixel P)

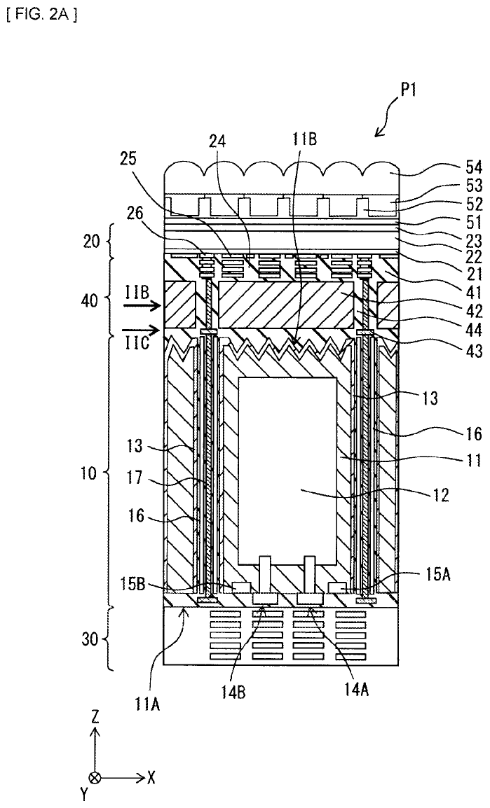

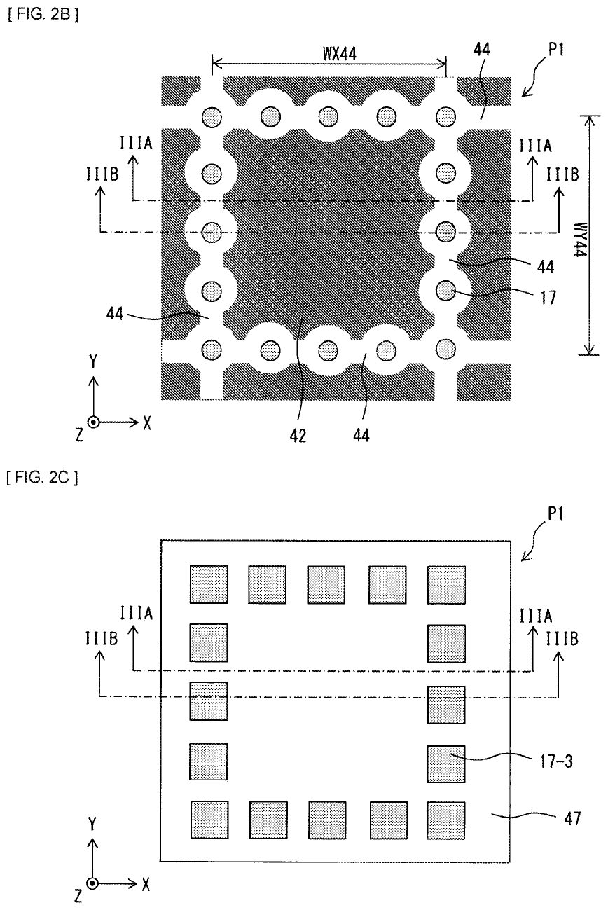

FIG. 2A schematically illustrates an exemplary vertical cross-sectional configuration, along the thickness direction, of one pixel P1 of the multiple pixels P arranged in matrix in the pixel unit 100. FIG. 2B schematically illustrates an exemplary horizontal cross-sectional configuration along a stacking plane direction perpendicular to the thickness direction at a height position in a Z-axis direction indicated by an arrow IIB in FIG. 2A. Further, FIG. 2C schematically illustrates an exemplary horizontal cross-sectional configuration along the stacking plane direction perpendicular to the thickness direction at a height position in the Z-axis direction indicated by an arrow IIC in FIG. 2A. In FIGS. 2A to 2C, the thickness direction (stacking direction) of the pixel P1 is the Z-axis direction, and planar directions parallel to the stacking plane perpendicular to the Z-axis direction are an X-axis direction and a Y-axis direction. It is to be noted that the X-axis direction, the Y-axis direction, and the Z-axis direction are perpendicular to each other.

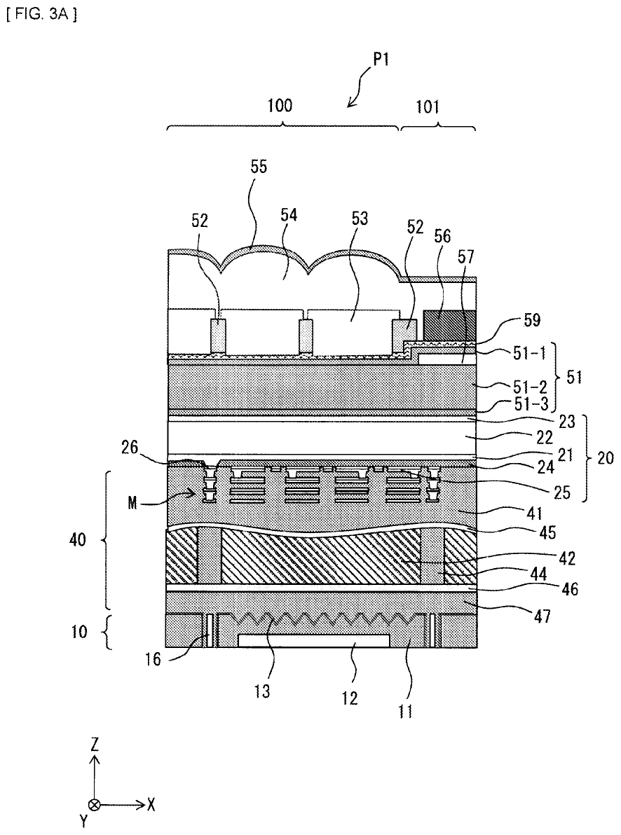

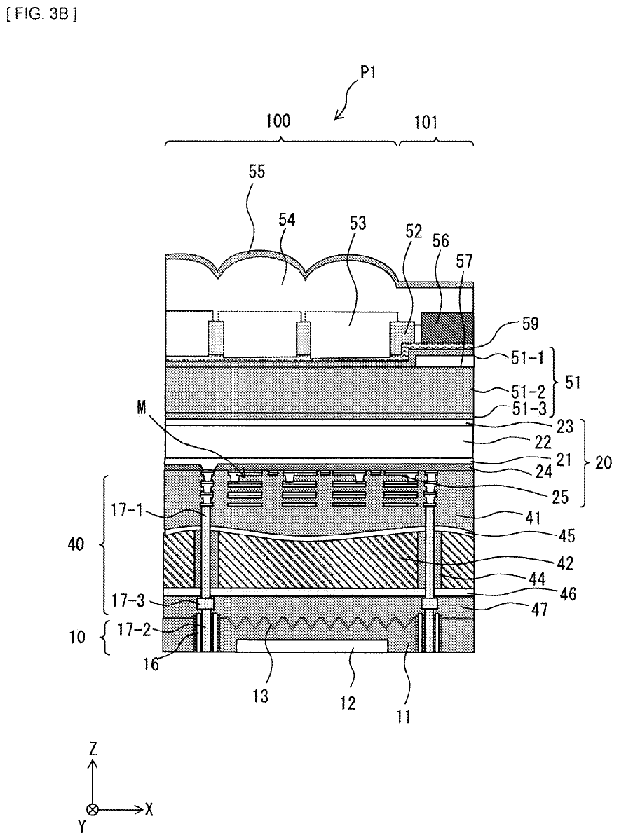

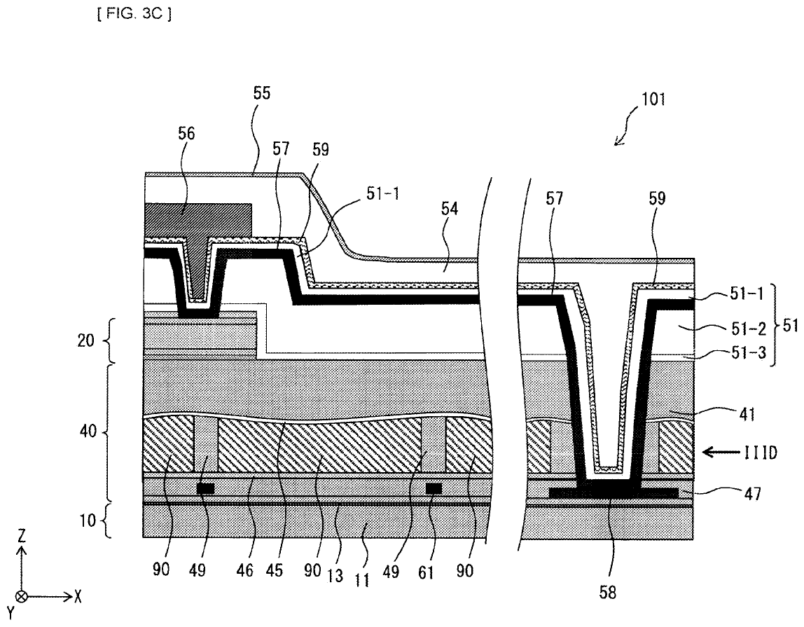

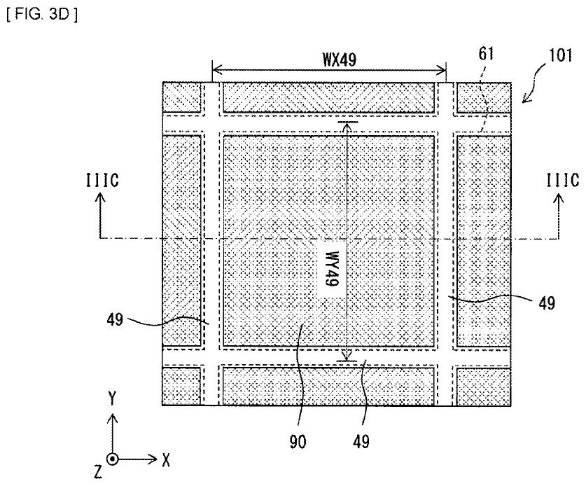

As illustrated in FIG. 2A, the pixel P1 is a so-called longitudinal spectroscopic imaging element having a configuration including one photoelectric conversion unit 10 and one organic photoelectric conversion unit 20 that are stacked in the Z-axis direction or the thickness direction, for example. The pixel P1 further includes an intermediate layer 40 provided between the photoelectric conversion unit 10 and the organic photoelectric conversion unit 20, and a multi-layer wiring layer 30 provided on a side opposite to the organic photoelectric conversion unit 20, as viewed from the photoelectric conversion unit 10. Further, as viewed from the organic photoelectric conversion unit 20, on a light-incident side opposite to the photoelectric conversion unit 10, for example, a sealing film 51, a partition wall 52, multiple color filters 53, and a lens layer 54 including an on-chip lens (OCL) provided corresponding to each of the multiple color filters 53 are stacked in the Z-axis direction in order from a position close to the organic photoelectric conversion unit 20. Further, as to be described later, a protection film 59 is further provided between the color filters 53 and the sealing film 51 (refer to FIGS. 3A to 3C to be described later). It is to be noted that the sealing film 51, the partition wall 52, and the protection film 59 may be provided in common among the multiple pixels P. The sealing film 51 is provided between the color filter 53 and the organic photoelectric conversion unit 20, and between the color filter 53 and a semiconductor layer 21 to be described later. The sealing film 51 may have a moisture permeability lower than that of the color filter 53. The sealing film 51 has a structure in which transparent insulating films 51-1 to 51-3 including, for example, AlOx are stacked. The sealing film 51 includes, for example, one or more of AlO, SiN, SiON, and TiO. In addition, an antireflection film 55 (described in, for example, FIG. 3A to be described later) may be provided so as to cover the lens layer 54. A black filter 56 may be provided in the peripheral unit 101. The multiple color filters 53 include, for example, a color filter that mainly transmits red light, a color filter that mainly transmits green light, and a color filter that mainly transmits blue light. The pixel P1 of the present embodiment includes red, green, and blue color filters 53. The organic photoelectric conversion unit 20 receives the red light, the green light, and the blue light to obtain color visible light images.

### (Photoelectric Conversion Unit 10)

The photoelectric conversion unit 10 is an indirect TOF (hereinafter referred to as iTOF) sensor that acquires a distance image (distance data) based on time-of-flight (TOF), for example. The photoelectric conversion unit 10 includes, for example, the semiconductor substrate 11, a photoelectric conversion region 12, a fixed charge layer 13, and a pair of transfer transistors (TGs) 14A and 14B, charge-voltage converters (FDs) 15A and 15B that are floating diffusion regions, an inter-pixel region light-shielding wall 16, and a through-electrode 17. The photoelectric conversion region 12 is a specific example corresponding to the “second photoelectric conversion layer” of the present disclosure.

The semiconductor substrate 11 is, for example, an n-type silicon (Si) substrate having a front face 11A and a rear face 11B. The semiconductor substrate 11 has a p-well in a predetermined region. The front face 11A faces the multi-layer wiring layer 30. The rear face 11B is a surface facing the intermediate layer 40, and may have a fine irregular structure (RIG structure). One reason for this is that light with a wavelength in an infrared light range as a second wavelength range (e.g., a wavelength within a range greater than or equal to 880 nm and less than or equal to 1040 nm) and incident on the semiconductor substrate 11 is effectively configured inside the semiconductor substrate 11. It is to be noted that the front face 11A may also have a similar fine irregular structure.

The photoelectric conversion region 12 is, for example, a photoelectric convertor configured by a positive intrinsic negative (PIN) photodiode (PD), and includes a pn junction formed in a predetermined region of the semiconductor substrate 11. The photoelectric conversion region 12 is provided so as to overlap the organic photoelectric conversion layer 22 in the Z-axis direction, and detects light in the wavelength range having transmitted through the organic photoelectric conversion layer 22 and performs photoelectric conversion. Out of the light received from the subject, light having a wavelength particularly in the infrared light range is detected and received by the photoelectric conversion region 12. The photoelectric conversion region 12 generates an electric charge corresponding to the amount of received light through photoelectric conversion and accumulates the electric charge.

The fixed charge layer 13 is provided so as to cover the rear face 11B of the semiconductor substrate 11, for example. The fixed charge layer 13 has, for example, a negative fixed charge to suppress the occurrence of a dark current due to an interface state of the rear face 11B that serves as a light-receiving face of the semiconductor substrate 11. A hole accumulation layer is formed in the vicinity of the rear face 11B of the semiconductor substrate 11 by an electric field induced by the fixed charge layer 13. The hole accumulation layer suppresses the generation of electrons from the rear face 11B. It is to be noted that the fixed charge layer 13 also includes a portion extending in the Z-axis direction between the inter-pixel region light-shielding wall 16 and the photoelectric conversion region 12. The fixed charge layer 13 is preferably formed using an insulating material. Specific examples of the constituent material of the fixed charge layer 13 include hafnium oxide (HfOx), aluminum oxide (AlOx), zirconium oxide (ZrOx), tantalum oxide (TaOx), titanium oxide (TiOx), lanthanum oxide (LaOx), praseodymium oxide (PrOx), cerium oxide (CeOx), neodymium oxide (NdOx), promethium oxide (PmOx), samarium oxide (SmOx), europium oxide (EuOx), gadolinium oxide (GdOx), terbium oxide (TbOx), dysprosium oxide (DyOx), holmium oxide (HoOx), thulium oxide (TmOx), ytterbium oxide (YbOx), lutetium oxide (LuOx), yttrium oxide (YOx), hafnium nitride (HfNx), aluminum nitride (AlNx), hafnium oxynitride (HfOxNy), and aluminum oxynitride (AlOxNy).

The paired TGs 14A and 14B each extend in the Z-axis direction from the front face 11A to the photoelectric conversion region 12, for example. The TGs 14A and the TG 14B transfer the electric charges accumulated in the photoelectric conversion region 12 to the paired FDs 15A and 15B in response to an application of a drive signal.

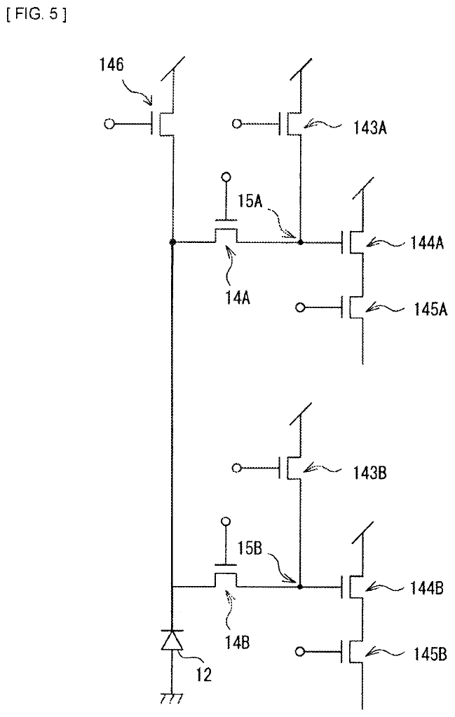

The paired FDs 15A and 15B are floating diffusion regions that convert electric charges transferred from the photoelectric conversion region 12 via the TGs 14A and 14B into electric signals (e.g., voltage signals) and output the signals. As illustrated in FIG. 5 to be described later, reset transistors (RSTs) 143A and 143B are coupled to the FDs 15A and 15B, respectively. In addition, the vertical signal line Lsig (illustrated in in FIG. 1A) is coupled to the FDs 15A and 15B via amplifier transistors (AMPs) 144A and 144B, selection transistors (SELs) 145A and 145B.

FIGS. 3A and 3B are enlarged cross-sectional views of a main portion of the pixel P1 illustrated in FIG. 2A. However, FIG. 3A illustrates a cross-section taken along a cut line IIIA-IIIA in the direction of an arrow indicated in FIGS. 2B and 2C, and FIG. 3B illustrates a cross-section taken along a cut line IIIB-IIIB in the direction of an arrow illustrated in FIGS. 2B and 2C. Further, FIG. 3C is a vertical cross-sectional view of an exemplary schematic configuration of the peripheral unit 101 illustrated in FIG. 1B. Further, FIG. 3D is an enlarged horizontal cross-sectional view of a portion of the peripheral unit 101 illustrated in FIG. 3C. FIG. 3D schematically illustrates a n example of the horizontal cross-sectional configuration at a height position in the Z-axis direction indicated by an arrow IIID in FIG. 3C. It is to be noted that FIG. 3C corresponds to a cross-section taken along a cut line IIIC-IIIC illustrated in FIG. 3D.

As illustrated in FIG. 3A, the partition wall 52 is provided in a gap between the color filters 53 arranged in the X-axis direction. Although FIG. 3A illustrates an exemplary cross-section parallel to an XZ plane, the cross-section parallel to the XZ plane of the pixel unit 100 has substantially the same configuration as the cross-section parallel to the XZ plane. The partition wall 52 has a refractive index lower than that of the color filter 53 adjacent to the partition wall 52. The partition wall 52 may include an insulating material. The partition wall 52 includes, for example, a low-temperature oxide (LTO) film. The LTO film is a silicon oxide film (SiOx) formed by low-temperature plasma-enhanced chemical vapor deposition (CVD) at a relatively low temperature of, for example, lower than or equal to 150° C.

Furthermore, the protection film 59 is provided between the color filter 53 and the sealing film 51 (refer to FIGS. 3A to 3C). It is to be noted that, in the present embodiment, the protection film 59 is provided between the color filter 53 and the partition wall 52, and between the color filter 53 and the sealing film 51. The protection film 59 protects the sealing film 51 when the color filter 53 is selectively etched. Therefore, the protection film 59 desirably has etching resistance to an alkaline developer higher than that of the sealing film 51. The protection film 59 may have an etching rate of, for example, less than or equal to 1 nm/min, with respect to the alkaline developer. The protection film 59 may be formed by, for example, an atomic layer deposition (ALD) method. The protection film 59 includes, for example, one or both of TiO₂ and SiN. The protection film 59 has a thickness of, for example, greater than or equal to 1 nm and less than or equal to 200 nm, and particularly, greater than or equal to 1 nm and less than or equal to 50 nm. The protection film 59 may be formed so as to entirely cover a portion of the sealing film 51 provided in the pixel unit 100 of the solid-state imaging apparatus 1, and a portion of the sealing film 51 provided in the peripheral unit 101. That is, the protection film 59 may be formed in both of the pixel unit 100 and the peripheral unit 101.

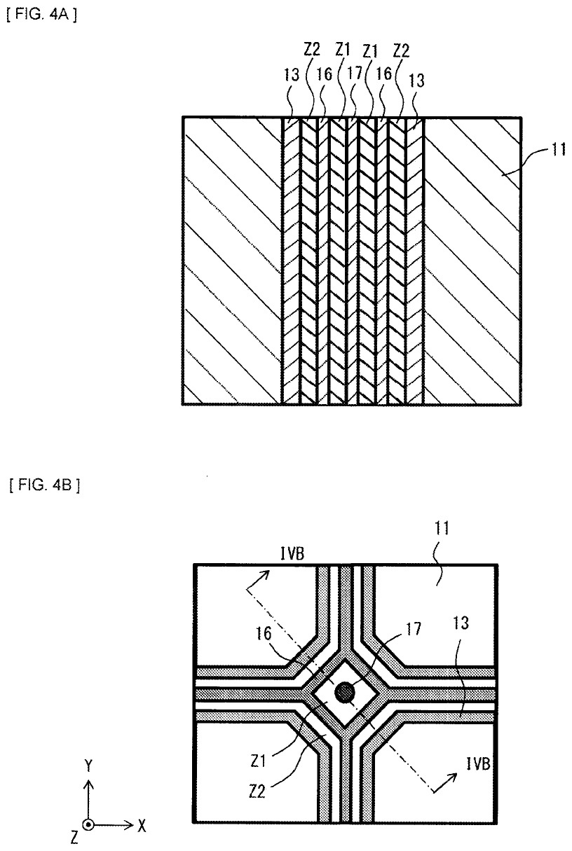

FIG. 4A is a cross-sectional view taken along the Z-axis and illustrating the inter-pixel region light-shielding wall 16 surrounding the through-electrode 17 in an enlarged manner. FIG. 4B is an enlarged cross-sectional view taken along the XY plane and illustrating the inter-pixel region light-shielding wall 16 surrounding the through-electrode 17. FIG. 4A illustrates a cross-section in an arrow direction along a line IVB-IVB illustrated in FIG. 4B. The inter-pixel region light-shielding wall 16 is provided at a boundary between adjacent pixels P on the XY plane. The inter-pixel region light-shielding wall 16 includes, for example, a portion extending along the XZ plane and a portion extending along a YZ plane, and is provided so as to surround the photoelectric conversion region 12 of each P. In addition, the inter-pixel region light-shielding wall 16 may be provided so as to surround the through-electrode 17. This suppresses oblique incidence of unwanted light on the photoelectric conversion region 12 between adjacent pixels P and prevents color mixing.

For example, the inter-pixel region light-shielding wall 16 includes a material including one or more of a single metal, a metal alloy, a metal nitride, and a metal silicide having a light-shielding property. More specifically, examples of the constituent material of the inter-pixel region light-shielding wall 16 include Al (aluminum), Cu (copper), Co (cobalt), W (tungsten), Ti (titanium), Ta (tantalum), Ni (nickel), Mo (molybdenum), Cr (chromium), Ir (iridium), platinum-iridium, TiN (titanium nitride), and tungsten-silicon compounds. It is to be noted that the constituent material of the inter-pixel region light-shielding wall 16 is not limited to a metal material, and may include graphite. The inter-pixel region light-shielding wall 16 is not limited to an electrically conductive material, and may include a non-conductive material having a light-shielding property such as an organic material. Further, an insulating layer Z1 including an insulating material such as SiOx (silicon oxide) or aluminum oxide may be provided between the inter-pixel region light-shielding wall 16 and the through-electrode 17. Alternatively, the inter-pixel region light shielding wall 16 and the through-electrode 17 may be insulated from each other by providing a gap between the inter-pixel region light shielding wall 16 and the through-electrode 17. When the inter-pixel region light-shielding wall 16 includes a non-conductive material, the insulating layer Z1 may not be provided. Further, an insulating layer Z2 may be provided outside the inter-pixel region light-shielding wall 16, that is, between the inter-pixel region light-shielding wall 16 and the fixed charge layer 13. The insulating layer Z2 includes an insulating material such as SiOx (silicon oxide) or aluminum oxide. Alternatively, the inter-pixel region light-shielding wall 16 and the fixed charge layer 13 may be insulated from each other by providing a gap between the inter-pixel region light-shielding wall 16 and the fixed charge layer 13. When the inter-pixel region light-shielding wall 16 includes an electrically conductive material, the insulating layer Z2 secures electrical insulation between the inter-pixel region light-shielding wall 16 and the semiconductor substrate 11. Further, when the inter-pixel region light-shielding wall 16 is provided so as to surround the through-electrode 17 and the inter-pixel region light-shielding wall 16 includes an electrically conductive material, the insulating layer Z1 secures electrical insulation between the inter-pixel region light-shielding wall 16 and the through-electrode 17.

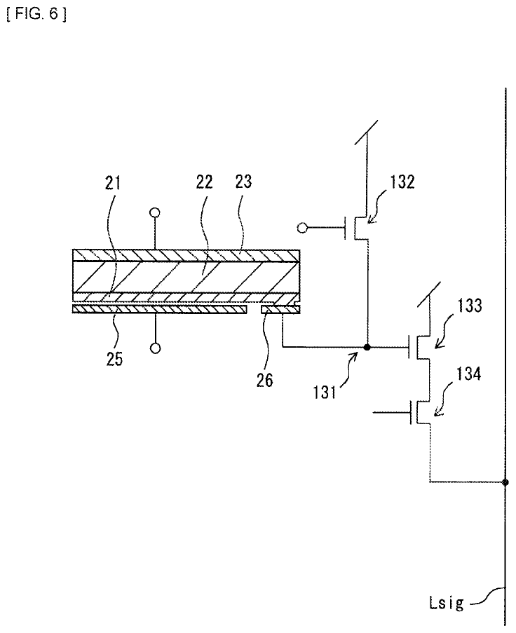

The through-electrode 17 is, for example, a coupling member that electrically couples a readout electrode 26 of the organic photoelectric conversion unit 20 provided on a side of the rear face 11B of the semiconductor substrate 11, and the FD 131 and the AMP 133 (refer to FIG. 6 to be described later) provided on the front face 11A of the semiconductor substrate 11. The through-electrode 17 serves as, for example, a transmission path through which a signal charge generated in the organic photoelectric conversion unit 20 or a voltage to drive a charge storage electrode 25 is transmitted. The through-electrode 17 may be provided so as to extend in the Z-axis direction, for example, from the readout electrode 26 of the organic photoelectric conversion unit 20 to the multi-layer wiring layer 30 through the semiconductor substrate 11. The through-electrode 17 is capable of properly transferring the signal charge generated in the organic photoelectric conversion unit 20 provided on the rear face 11B of the semiconductor substrate 11 to the front face 11A of the semiconductor substrate 11. As illustrated in FIGS. 2B and 3B, the through-electrode 17 extends through the inside of an inter-pixel region light-shielding wall 44 in the Z-axis direction. That is, the fixed charge layer 13 and the inter-pixel region light-shielding wall 44 having an electrical insulating property (to be described later) are provided around the through-electrode 17. This electrically insulates the through-electrode 17 and a p-well region of the semiconductor substrate 11 from each other. Further, the through-electrode 17 includes a first through-electrode portion 17-1 that extends through the inside of the inter-pixel region light-shielding wall 44 in the Z-axis direction, and a second through-electrode portion 17-2 that extends through the inside of the inter-pixel region light-shielding wall 16 in the Z-axis direction. The first through-electrode portion 17-1 and the second through-electrode portion 17-2 are coupled to each other via a coupling electrode portion 17-3, for example. A maximum dimension of the coupling electrode portion 17-3 in the XY in-plane direction is larger than both of a maximum dimension of the first through-electrode portion 17-1 in the XY in-plane direction and a maximum dimension of the second through-electrode portion 17-2 in the in-plane direction, for example.

The through-electrode 17 may be formed using, for example, one or more of metal materials including aluminum (Al), tungsten (W), titanium (Ti), cobalt (Co), platinum (Pt), palladium (Pd), copper (Cu), hafnium (Hf), and tantalum (Ta), in addition to an impurity-doped silicon material such as phosphorus-doped amorphous silicon (PDAS).

### (Multi-Layer Wiring Layer 30)

The multi-layer wiring layer 30 includes, for example, the RSTs 143A and 143B, the AMPs 144A and 144B, and the SELs 145A and 145B that form a readout circuit together with the TGs 14A and 14B.

### (Intermediate Layer 40)

The intermediate layer 40 may include, for example, an insulating layer 41 and an optical filter 42 embedded in the insulating layer 41. The intermediate layer 40 may further include the inter-pixel region light-shielding wall 44 serving as a first light-shielding member that shields at least light having a wavelength in an infrared light range (for example, a wavelength equal to or greater than 880 nm and less than or equal to 1040 nm) as a second wavelength region. The insulating layer 41 includes, for example, a single-layer film that includes one of inorganic insulating materials including silicon oxide (SiOx), silicon nitride (SiNx), and silicon oxynitride (SiON), or a multi-layer film that includes two or more of these materials. Further, as a material constituting the insulating layer 41, an organic insulating material such as polymethyl methacrylate (PMMA), polyvinyl phenol (PVP), polyvinyl alcohol (PVA), polyimide, polycarbonate (PC), polyethylene terephthalate (PET), polystyrene, N-2 (aminoethyl) 3-aminopropyltrimethoxysilane (AEAPTMS), 3-mercaptopropyltrimethoxysilane (MPTMS), tetraethoxysilane (TEOS), or octadecyltrichlorosilane (OTS) may be used. Further, a wiring layer M is buried in the insulating layer 41. The wiring layer M is coupled to the charge storage electrode 25 to be described later and the like, and includes various wires that include a transparent conductive material and. The inter-pixel region light-shielding wall 44 is a single-layer film including one of inorganic insulating materials that mainly block light in an infrared light range, including silicon oxide (SiOx), silicon nitride (SiNx), and silicon oxynitride (SiON), or a multi-layer film including two or more of these materials. The inter-pixel region light-shielding wall 44 may be formed integrally with the insulating layer 41. The inter-pixel region light-shielding wall 44 surrounds the optical filter 42 along the XY plane so as to overlap with at least a portion of the optical filter 42 in the XY plane perpendicular to the thickness direction (Z-axis direction). Like the inter-pixel region light-shielding wall 16, the inter-pixel region light-shielding wall 44 suppresses oblique incidence of unwanted light on the photoelectric conversion region 12 between adjacent pixels P1 and prevents color mixing.

The optical filter 42 has a transmission band in the infrared light range in which photoelectric conversion is performed in the photoelectric conversion region 12. That is, the optical filter 42 transmits light having a wavelength in the infrared light range, that is, infrared light more easily than light having a wavelength in a visible light range as a first wavelength range (e.g., a wavelength greater than or equal to 400 nm and less than or equal to 700 nm), that is, visible light. Specifically, the optical filter 42 may include, for example, an organic material, and is configured to absorb at least a portion of light having a wavelength in the visible light range while selectively transmitting light in the infrared light range. The optical filter 42 includes, for example, an organic material such as a phthalocyanine derivative. The plurality of optical filters 42 provided in the pixel unit 100 may have substantially the same shape and substantially the same size as each other.

A SiN layers 45 may be provided on a rear face, that is, a surface facing the organic photoelectric conversion unit 20 of the optical filters 42. In addition, a SiN layers 46 may be provided on a front face, that is, a surface facing the photoelectric conversion unit 10, of the optical filters 42. Further, an insulating layer 47 including, for example, SiOx may be provided between the semiconductor substrate 11 and the SiN layer 46.

### (Organic Photoelectric Conversion Unit 20)

The organic photoelectric conversion unit 20 includes, for example, the readout electrode 26, the semiconductor layer 21, the organic photoelectric conversion layer 22, and an upper electrode 23 that are stacked in order from a position close to the photoelectric conversion unit 10. The organic photoelectric conversion layer 22 is located between the semiconductor layer 21 and the color filter 53. The organic photoelectric conversion unit 20 further includes an insulating layer 24 provided below the semiconductor layer 21, and the charge storage electrode 25 provided to face the semiconductor layer 21 with the insulating layer 24 interposed therebetween. The charge storage electrode 25 and the readout electrode 26 are spaced apart from each other, and are provided, for example, at the same layer level. The readout electrode 26 is in contact with an upper end of the through-electrode 17. In addition, the organic photoelectric conversion unit 20 is coupled to the lead-out wire 58 via the contact layer 57 in the peripheral unit 101, as illustrated in FIG. 3C, for example. Note that the upper electrode 23, the organic photoelectric conversion layer 22, and the semiconductor layer 21 may be commonly provided among some pixels P1 of the multiple pixels P1 in the pixel unit 100 (FIG. 2A), or may be commonly provided among all of the multiple pixels P in the pixel unit 100. The same applies to modification examples described below. Here, the organic photoelectric conversion layer 22 is a specific example corresponding to a “first photoelectric conversion layer” of the present disclosure.

It is to be noted that another organic layer may be provided between the organic photoelectric conversion layer 22 and the semiconductor layer 21 and between the organic photoelectric conversion layer 22 and the upper electrode 23.

The readout electrode 26, the upper electrode 23, and the charge storage electrode 25 include an electrically conductive film having a light-transmitting property, and include, for example, ITO (indium-tin oxide). However, as constituent materials of the readout electrode 26, the upper electrode 23, and the charge storage electrode 25, a tin oxide (SnOx)-based material to which a dopant is added, or a zinc oxide-based material obtained by adding a dopant to a zinc oxide (ZnO) may be used, in addition to ITO. Examples of the zinc oxide-based material include aluminum zinc oxide (AZO) to which aluminum (Al) is applied as a dopant, gallium zinc oxide (GZO) to which gallium (Ga) is applied, and indium zinc oxide (IZO) to which indium (In) is applied. In addition, CuI, InSbO₄, ZnMgO, CuInO₂, MgIN₂O₄, CdO, ZnSnO₃, a TiO₂, or the like may be used as a constituent material of the readout electrode 26, the upper electrode 23, and the charge storage electrode 25. Further, a spinel-type oxide or an oxide having a YbFe₂O₄ structure may be used.

The organic photoelectric conversion layer 22 converts light energy into electric energy, and includes two or more kinds of organic materials that serve as a p-type semiconductor and an n-type semiconductor, for example. The p-type semiconductor relatively serves as an electron donor, and an n-type semiconductor serves as an n-type semiconductor that relatively serves as an electron acceptor. The organic photoelectric conversion layer 22 has a bulk heterojunction structure in the layer. The bulk-heterojunction structure is a p/n junction surface formed by mixing the p-type semiconductor and the n-type semiconductor, and excitons generated upon absorption of light are separated into electrons and holes at the p/n junction interface.

In addition to the p-type semiconductor and the n-type semiconductor, the organic photoelectric conversion layer 22 may further include three types of so-called dye materials that photoelectrically convert light in a predetermined wavelength band while transmitting light in another wavelength band. The p-type semiconductor, the n-type semiconductor, and the dye materials preferably have absorption maximum wavelengths different from each other. This makes it possible to absorb the wavelength in the visible light range in a wide range.

The organic photoelectric conversion layer 22 may be formed, for example, by mixing the various organic semiconductor materials described above and using a spin coating technique. Alternatively, the organic photoelectric conversion layer 22 may be formed using, for example, a vacuum deposition method, a printing technique, or the like.

As a constituent material of the semiconductor layer 21, it is preferable to use a material having a high bandgap value (for example, a bandgap value greater than or equal to 3.0 eV) and a higher mobility than the constituent material of the organic photoelectric conversion layer 22. Specific examples thereof include oxide semiconductor materials such as IGZO; transition-metal dichalcogenides; silicon carbides; diamonds; graphene; carbon nanotubes; and organic semiconductor materials such as condensed polycyclic hydrocarbon compounds and condensed heterocyclic compounds.

The semiconductor layer 21 is a specific example corresponding to an “oxide semiconductor” of the present disclosure.

The charge storage electrode 25 forms a kind of capacitor together with the insulating layer 24 and the semiconductor layer 21, and accumulates electric charges generated in the organic photoelectric conversion layer 22 in a portion of the semiconductor layer 21, for example, a region portion of the semiconductor layer 21 corresponding to the charge storage electrode 25 via the insulating layer 24. In the present embodiment, for example, one charge storage electrode 25 is provided corresponding to each of one color filter 53 and one on-chip lens, respectively. The charge storage electrode 25 is coupled to, for example, the vertical drive circuit 111.

The insulating layer 24 may be formed of, for example, an inorganic insulating material and an organic insulating material that are similar to those of the insulating layer 41.

As described above, the organic photoelectric conversion unit 20 detects a part or all of the wavelength in the visible light range. In addition, it is desirable that the organic photoelectric conversion unit 20 have no sensitivity to the infrared light range.

In the organic photoelectric conversion unit 20, light incident from the upper electrode 23 side is absorbed by the organic photoelectric conversion layer 22. The exciton (electron-hole pair) generated thereby moves to the interface between the electron donor and the electron acceptor constituting the organic photoelectric conversion layer 22, and is subjected to exciton separation, that is, dissociated into an electron and a hole. The electric charge generated here, i.e., the electron and the hole, are transferred to the upper electrode 23 or the semiconductor layer 21 by diffusion due to a difference in concentration of carriers or by an internal electric field due to a difference in potential between the upper electrode 23 and the charge storage electrode 25, and are detected as a photocurrent. For example, the readout electrode 26 is set to a positive potential, and the upper electrode 23 is set to a negative potential. In this case, the hole generated by the photoelectric conversion in the organic photoelectric conversion layer 22 moves to the upper electrode 23. The electron generated by the photoelectric conversion in the organic photoelectric conversion layer 22 is attracted to the charge storage electrode 25 and accumulated in a portion of the semiconductor layer 21, for example, a region portion of the semiconductor layer 21 corresponding to the charge storage electrode 25 via the insulating layer 24.

The electric charges (e.g., electrons) accumulated in the region portion of the semiconductor layer 21 corresponding to the charge storage electrode 25 via the insulating layer 24 are read out as follows. Specifically, a potential V26 is applied to the readout electrode 26, and a potential V25 is applied to the charge storage electrode 25. Here, the potential V26 is higher than the potential V25 (V25<V26). In this way, the electrons accumulated in the region portion of the semiconductor layer 21 corresponding to the charge storage electrode 25 are transferred to the readout electrode 26.

As described above, the semiconductor layer 21 is provided under the organic photoelectric conversion layer 22, and electric charges (e.g., electrons) are accumulated in the region portion of the semiconductor layer 21 corresponding to the charge storage electrode 25 via the insulating layer 24. This provides the following effects. That is, as compared with the case where electric charges (e.g., electrons) are accumulated in the organic photoelectric conversion layer 22 without providing the semiconductor layer 21, it is possible to prevent holes and electrons from recombining during the electric charge accumulation, to increase the transfer efficiency of the accumulated electric charges (e.g., electrons) to the readout electrode 26, and to suppress generation of a dark current. Although the example where the electrons are read out is described above, the holes may be read out. In the case of reading out the holes, the potential in the above description is described as the potential sensed by the holes.

As illustrated in FIGS. 3C and 3D, the peripheral unit 101 may be provided with an optical filter 90 as a second optical filter. Like the optical filter 42 provided in the pixel unit 100, the optical filter 90 transmits infrared light more easily than visible light. The optical filter 90 may be provided at the same layer level as the layer at which the optical filter 42 is provided, for example. A constituent material of the optical filter 90 may be substantially the same as or different from the constituent material of the optical filter 42. For example, the optical filter 42 and the optical filter 90 may include substantially the same organic material as each other. Alternatively, the peripheral unit 101 may be provided with multiple optical filters 90, and the multiple optical filters 90 may be each surrounded by a peripheral region light-shielding wall 49 serving as a second light-shielding member that shields at least infrared light, along the XY plane perpendicular to the Z-axis direction. Further, the multiple optical filters 90 provided in the peripheral unit 101 may have substantially the same shape and substantially the same size as each other.

Further, for example, an arrangement pitch WX44 (refer to FIG. 2B) of the inter-pixel region light-shielding walls 44 arranged in the X-axis direction may be substantially equal to an arrangement pitch WX49 (refer to FIG. 3D) of the peripheral region light-shielding walls 49 arranged in the X-axis direction. Similarly, an arrangement pitch WY44 (refer to FIG. 2B) of the inter-pixel region light-shielding walls 44 arranged in the Y-axis direction may be substantially equal to an arrangement pitch WY49 (refer to FIG. 3D) of the peripheral region light-shielding walls 49 arranged in the Y-axis direction. It is to be noted that the arrangement pitch WX44 and the arrangement pitch WX49 may be substantially equal to the arrangement pitch WY44 and the arrangement pitch WY49, respectively. Alternatively, the arrangement pitch WX44 and the arrangement pitch WX49 may be different from the arrangement pitch WY44 and the arrangement pitch WY49, respectively. Further, a planar shape of the optical filter 90 along the XY plane partitioned by the peripheral region light-shielding wall 49 is not limited to a substantially rectangular shape, and may be a polygon, such as a hexagon, other than a quadrangle, for example, or may be a circular shape or an oval shape, for example.

The peripheral unit 101 may be further provided with a light shielding film 60 provided so as to overlap with the peripheral region light-shielding wall 49 in the Z-axis direction. The light shielding film 60 is provided, for example, in a layer between the semiconductor substrate 11 and the SiN layer 46, but is not limited thereto. The light shielding film 60 may include a metal material such as W (tungsten). The light shielding film 60 reflects visible light or absorbs visible light.

### (Readout Circuit of Photoelectric Conversion Unit 10)

FIG. 5 is a circuit diagram illustrating an exemplary readout circuit of the photoelectric conversion unit 10 constituting the pixel P illustrated in FIG. 2A.

The readout circuit of the photoelectric conversion unit 10 includes, for example, the TGs 14A and 14B, an OFG 146, the FDs 15A and 15B, the RSTs 143A and 143B, the AMPs 144A and 144B, and the SELs 145A and 145B.

The TGs 14A and 14B are coupled between the photoelectric conversion region 12 and the FD 15A, and between the photoelectric conversion region 12 and the FD 15B. When the TGs 14A and 14B are activated in response to an application of a drive signal to gate electrodes of the TGs 14A and 14B, transfer gates of the TGs 14A and 14B are energized. As a result, the signal charge converted in the photoelectric conversion region 12 is transferred to the FDs 15A and 15B via the TGs 14A and 14B.

The OFG 146 is coupled between the photoelectric conversion region 12 and a power source. When the OFG 146 is activated in response to an application of a drive signal to a gate electrode of the OFG 146, the OFG 146 is energized. As a result, the signal charge converted in the photoelectric conversion region 12 is discharged to the power source via the OFG 146.

The FD 15A is coupled to between the TG 14A and the AMP 144A, and the FD 15B is coupled to between the TG 14B and the AMP 144B. The FDs 15A and 15B convert the signal charge transferred by the TGs 14A and 14B into voltage signals and output the voltage signals to the AMPs 144A and 144B.

The RST 143A is coupled to between the FD 15A and the power source, and the RST 143B is coupled to between the FD 15B and the power source. When the RSTs 143A and 143B are activated in response to an application of a drive signal to gate electrodes of the RSTs 143A and 143B, reset gates of the RSTs 143A and 143B are energized. As a result, the potentials of the FDs 15A and 15B are reset to the level of the power source.

The AMP 144A has a gate electrode coupled to the FD 15A and a drain electrode coupled to the power source. The AMP 144B has a gate electrode coupled to the FD 15B and a drain electrode coupled to the power source. The AMPs 144A and 144B serve as input units of circuitry that reads out voltage signals held by the FDs 15A and 15B, that is, so-called source follower circuitry. That is, a source electrode of the AMP 144A is coupled to the vertical signal line Lsig via the SEL 145A, and a source electrode of the AMP 144B is coupled to the vertical signal line Lsig via the SEL 145B, forming a constant current source and the source follower circuitry that are coupled to one end of the vertical signal line Lsig.

The SEL 145A is coupled to between the source electrode of the AMP 144A and the vertical signal line Lsig. The SEL 145B is coupled to between the source electrode of the AMP 144B and the vertical-signal line Lsig. When the SELs 145A and 145B are activated in response to an application of a driving signal to the gate electrodes of the SELs 145A and 145B and, the SELs 145A and 145B are energized, and the pixel P is selected. As a result, read signals (pixel signals) outputted from the AMPs 144A and 144B are outputted to the vertical signal line Lsig via the SELs 145A and 145B.

In the solid-state imaging apparatus 1, a light pulse in the infrared range is incident on a subject, and the light pulse reflected from the subject is received in the photoelectric conversion region 12 of the photoelectric conversion unit 10. In the photoelectric conversion region 12, a plurality of electric charges is generated by the incidence of light pulses in the infrared range. The plurality of electric charges generated in the photoelectric conversion regions 12 is alternately distributed to the FD 15A and the FD 15B by alternately supplying driving signals to the paired TGs 14A and 14B for equal periods of time. By changing a shutter phase of the drive signal applied to the TGs 14A and 14B, the amount of electric charges accumulated in the FD 15A and the amount of electric charge accumulated in the FD 15B are phase-modulated. Since round-trip time of the light pulse is estimated by demodulating them, the distance between the solid-state imaging apparatus 1 and the subject is obtained.

### (Readout Circuit of Organic Photoelectric Conversion Unit 20)

FIG. 6 is a circuit diagram illustrating an exemplary readout circuit of the organic photoelectric conversion unit 20 included in the pixel P1 illustrated in FIG. 2A.

The readout circuit of the organic photoelectric conversion unit 20 includes, for example, a FD 131, a RST 132, an AMP 133, and a SEL 134.

The FD 131 is coupled to between a readout electrode 26 and the AMP 133. The FD 131 converts the signal charge transferred by the readout electrode 26 into a voltage signal and outputs the voltage signal to the AMP 133.

The RST 132 is coupled to between the FD 131 and the power source. When the RST 132 is activated in response to an application of a drive signal to a gate electrode of the RST 132, a reset gate of the RST 132 is energized. As a result, the potential of the FD 131 is reset to the level of the power source.

The AMP 133 has a gate electrode coupled to the FD 131 and a drain electrode coupled to the power source. The AMP 133 has a source electrode coupled to the vertical signal line Lsig via the SEL 134.

The SEL 134 is coupled to between the source electrode of the AMP 133 and the vertical signal line Lsig. When The SEL 134 is activated in response to an application of a drive signal to a gate electrode of the SEL 134, the SEL 134 is energized, and the pixel P1 is selected. As a result, a readout signal (pixel signal) outputted from the AMP 133 is outputted to the vertical signal line Lsig via the SEL 134.

### [Workings and Effects of Solid-State Imaging Apparatus 1]

The solid-state imaging apparatus 1 of the present embodiment includes the organic photoelectric conversion unit 20, the optical filter 42, and the photoelectric conversion unit 10 that are stacked in this order from the incident side. The organic photoelectric conversion unit 20 detecting light with a wavelength in the visible light range and perform photoelectric conversion. The optical filter 42 has a transmission band in the infrared light range. The photoelectric conversion unit 10 detects light with a wavelength in the infrared light range and perform photoelectric conversion. Therefore, it is possible to simultaneously acquire, at the same position in the XY plane, a visible light image including a red light signal, a green light signal, and a blue light signal obtained from the red pixel PR, the green pixel PG, and the blue pixel PB, respectively, and the infrared light image using the infrared light signal obtained from all of the multiple pixels P. This achieves high integration in the XY plane.

In the solid-state imaging apparatus 1 of the present embodiment, the partition wall 52 having a refractive index lower than that of the color filter 53 is provided in a gap between the color filters of adjacent pixels P of the multiple pixels P. Therefore, it is possible to prevent irradiation light having entered the color filter 53 from leaking from the color filter to the surroundings. Therefore, the sensitivity of the incident light in each pixel P is improved. In addition, since it is possible to avoid unintentional incidence of the leaked light from the adjacent pixels P into the organic photoelectric conversion layer 22, it is possible to avoid color mixing between the pixels P.

Further, in the solid-state imaging apparatus 1 of the present embodiment, the partition wall 52 includes SiOx capable of forming a film at a temperature of lower than or equal to 150° C. by low-temperature plasma chemical vapor deposition. In general, an organic semiconductor including an organic photoelectric conversion layer can decompose when being heated at a temperature higher than 150° C. In this regard, in the present embodiment, the partition wall 52 is formed at a low temperature of lower than or equal to 150° C. as described above. Therefore, it is possible in the present embodiment to stably maintain the organic film such as the organic photoelectric conversion layer 22 in the process for manufacturing thereof. As a result, more favorable imaging performance is ensured.

Further, in the solid-state imaging apparatus 1 of the present embodiment, the sealing film 51 having a moisture transmittance lower than that of the color filter 53 is provided between the color filter 53 and the organic photoelectric conversion layer 22, and between the color filter 53 and the semiconductor layer 21. Therefore, the sealing film 51 prevents moisture and hydrogen contained in, for example, the LTO film constituting the partition wall 52 from entering the organic photoelectric conversion unit 20. Hydrogen can cause a reduction reaction of an oxide semiconductor. In addition, moisture can deteriorate a photoelectric conversion characteristic of an organic photoelectric conversion layer. Therefore, in the present embodiment, entry of hydrogen into the semiconductor layer 21 and entry of moisture into the organic photoelectric conversion layer 22 are suppressed by providing the sealing film 51. As a result, it is possible to maintain the operation performance of the organic photoelectric conversion unit 20 and to improve the reliability.

Further, in the present embodiment, the protection film 59 is provided between the color filter 53 and the sealing film 51. If the protection film 59 is not provided, the sealing film 51 can be damaged when the color filter 53 is selectively etched for patterning the color filter 53, for example, and the structural homogeneity of the sealing film 51 can be impaired. The protection film 59 has an etching resistance to an alkaline developer than higher than that of the sealing film 51. Therefore, during the selective etching of the color filter 53, the sealing film 51 is protected from being damaged. As a result, it is possible to suppress the entry of hydrogen into the semiconductor layer 21 and the entry of moisture into the organic photoelectric conversion layer 22 as described above.

Further, since the photoelectric conversion unit 10 has the paired TGs 14A and 14B and the paired FDs 15A and 15B, it is possible to acquire an infrared light image as a distance image including data on a distance to a subject. Therefore, according to the solid-state imaging apparatus 1 of the present embodiment, it is possible to acquire both of a high-resolution visible light image and an infrared light image having depth data.

Further, in the pixel P1 of the present embodiment, the inter-pixel region light-shielding wall 44 is provided that surrounds the optical filters 42. Therefore, it is possible to prevent leakage light from other adjacent pixel P1 or unwanted light from the surroundings from entering the photoelectric conversion unit 10 directly or through the optical filter 42. It is therefore possible to reduce noises to be received by the photoelectric conversion unit 10, and it is expected that S/N ratio, resolution, distance measurement accuracy, and the like of the solid-state imaging apparatus 1 are improved.

In the solid-state imaging apparatus 1 according to the embodiment of the present disclosure, the optical filter 90 that transmits infrared light more easily than visible light is provided in the peripheral unit 101 adjacent to the pixel unit 100 that detects visible light and performs photoelectric conversion. Therefore, it is possible to prevent visible light of the unwanted light incident on the peripheral unit 101 from entering the photoelectric conversion unit 10 directly or through the optical filter 90. It is therefore possible to further reduce the noises to be received by the photoelectric conversion unit 10, and it is expected that the S/N ratio, the resolution, the distance measurement accuracy, and the like of the solid-state imaging apparatus 1 are improved.

In addition, when the optical filter 42 and the optical filter 90 in the solid-state imaging apparatus 1 are formed using an organic material, for example, the optical filter 42 and the optical filter 90 are collectively formed by a coating method. At this time, since the optical filter 90 is disposed so as to surround the optical filter 42 located in the pixel unit 100, the flatness of the multiple optical filters 42 on the XY plane is improved, and variations in the thickness of the multiple optical filters 42 are further reduced. Therefore, variations in the sensitivity of detecting infrared light between the pixels P1 in the pixel unit 100 are reduced. Accordingly, the solid-state imaging apparatus 1 makes it possible to exhibit better imaging performance.

Further, in the pixel P1 of the present embodiment, the organic photoelectric conversion unit 20 includes the insulating layer 24 provided below the semiconductor layer 21, and the charge storage electrode 25 provided so as to face the semiconductor layer 21 via the insulating layer 24, in addition to the structure in which the readout electrode 26, the semiconductor layer 21, the organic photoelectric conversion layer 22, and the upper electrode 23 are stacked in this order. Therefore, electric charges generated by photoelectric conversion in the organic photoelectric conversion layer 22 is accumulated in a portion of the semiconductor layer 21, for example, the region portion of the semiconductor layer 21 corresponding to the charge storage electrode 25 via the insulating layer 24. It is therefore possible to achieve, for example, electric charge removal in the semiconductor layer 21 at the start of exposure, that is, complete depletion of the semiconductor layer 21. This reduces kTC noise, suppressing the deterioration of the image quality due to random noises. Further, as compared with the case where electric charges (e.g., electrons) are accumulated in the organic photoelectric conversion layer 22 without providing the semiconductor layer 21, it is possible to prevent holes and electrons from recombining during the electric charge accumulation, to increase the transfer efficiency of the accumulated electric charges (e.g., electrons) to the readout electrode 26, and to suppress generation of a dark current.

Further, in the pixel P1 of the present embodiment, the plurality of on-chip lens, the plurality of color filters 53, and the plurality of charge storage electrodes 25 are provided at positions overlapping each other in the Z-axis direction with respect to one photoelectric conversion region 12. Therefore, if at least some of the plurality of color filters 53 are different colors from each other, it is possible to reduce the difference in infrared light detection sensitivity, as compared with a case where one on-chip lens, one color filter 53, one charge storage electrode 25, and one photoelectric conversion region 12 are provided at respective positions in the Z-axis direction. In general, when one on-chip lens, one color filter 53, one charge storage electrode 25, and one photoelectric conversion region 12 are provided at respective positions in the Z-axis direction, the transmittance of infrared light traveling through the color filter 53 differs depending on the color of the color filter 53. Therefore, the intensity of the infrared light reaching the photoelectric conversion region 12 is different between the red pixel, the blue pixel, and the green pixel, for example. As a result, the infrared light detection sensitivity varies between the multiple pixels. In this regard, according to the pixel P1 of the present embodiment, the infrared light traveling through the plurality of color filters 53 enter the respective photoelectric conversion regions 12. Therefore, it is possible to reduce the difference in the infrared light-detection sensitivity that occurs between the plurality of pixels P1.

In the present embodiment, the red, green, and blue color filters 53 are provided, and the red, green, and blue light are received to acquire a color visible light image. However, a black-and-white visible light image may be acquired without providing the color filter 53.

### (First Modification Example of First Embodiment)

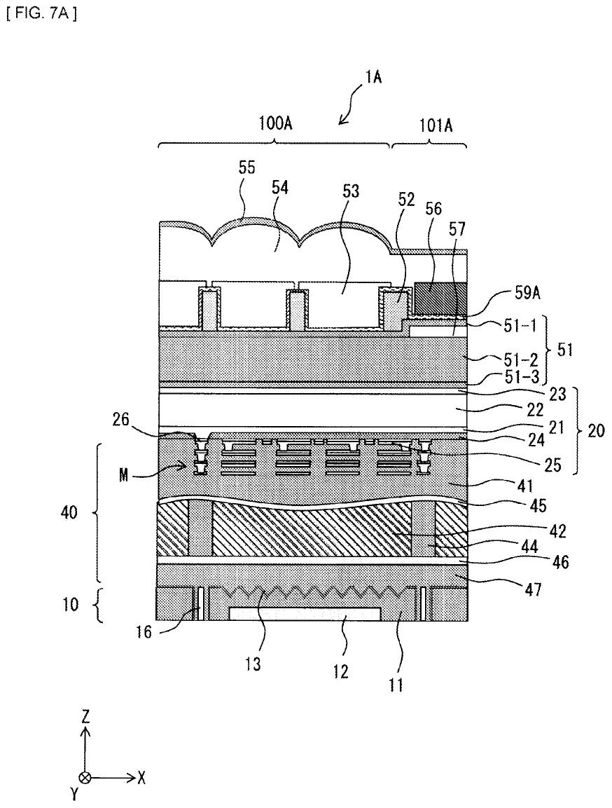

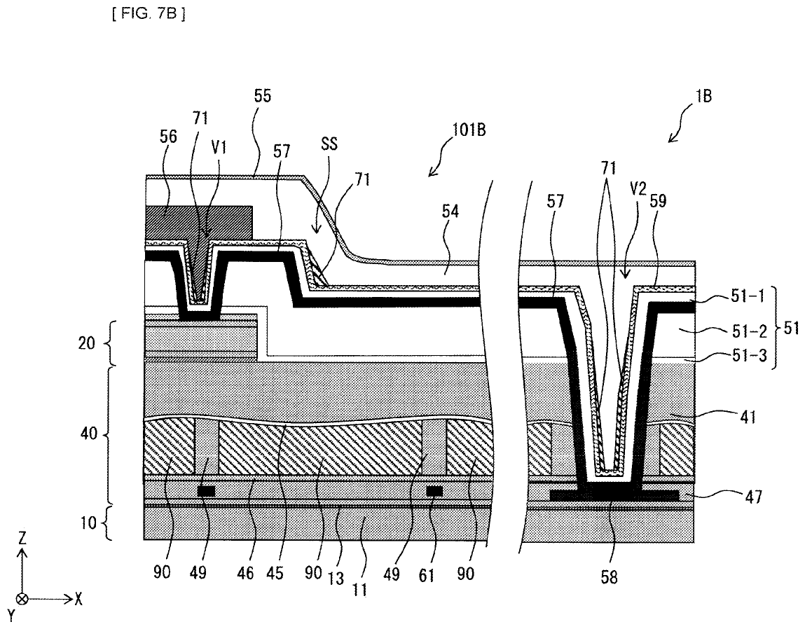

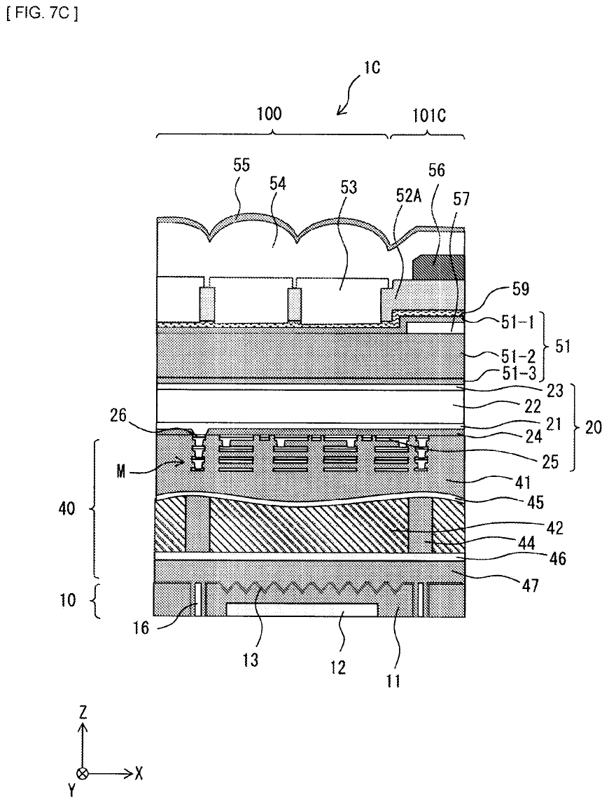

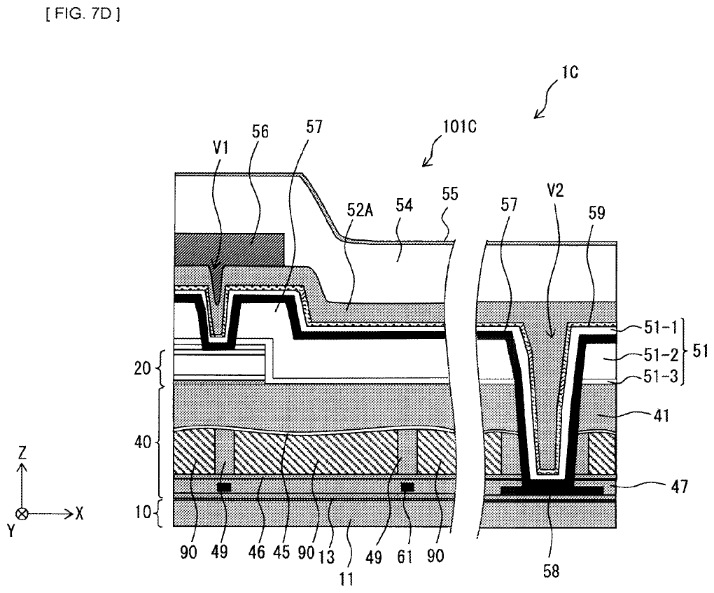

FIG. 7A schematically illustrates an example of a vertical cross-sectional configuration in a thickness direction of a solid-state imaging apparatus 1A according to a first modification example (Modification Example 1-1) of the first embodiment. According to the present disclosure, the protection film 59 may be provided so as to cover the partition wall 52 and the sealing film 51, as in the pixel unit 100A and the peripheral unit 101A illustrated in FIG. 7A. That is, the protection film 59 may be provided between the color filter 53 and the partition wall 52, and between the color filter 53 and the sealing film 51. In such a configuration, when the partition wall 52 is a LTO film including moisture and hydrogen, for example, the protection film 59 makes it possible to prevent the moisture and hydrogen from entering the color filters 53. As a result, it is possible to suppress deterioration of the color filter 53. Alternatively, the protection film 59 may include, for example, SiO₂.

### (Second Modification Example of First Embodiment)

FIG. 7B illustrates a vertical cross-sectional configuration of a peripheral unit 101B of a solid-state imaging apparatus 1B according to a second modification example (Modification Example 1-2) of the first embodiment. In the present modification example, a sidewall part 71 is provided. The sidewall part 71 is provided to cover, for example, a coupling portion between the contact layer 57 and the organic photoelectric conversion unit 20, a coupling portion between the contact layer 57 and the lead-out wire 58, or a steep wall surface of another step section. Specifically, in the peripheral unit 101B, for example, the sidewall part 71 is provided along a portion of a bottom surface of a groove V1 and a portion of a side wall surface of the groove V1 provided in the coupling portion between the contact layer 57 and the organic photoelectric conversion unit 20. Further, the sidewall part 71 is provided along a portion of a bottom surface of a groove V2 and a portion of a side wall surface of a groove V2 provided in the coupling portion between the contact layer 57 and the lead-out wire 58. Further, the sidewall part 71 is provided so as to cover a steep wall surface of a step section SS. The sidewall part 71 includes the same material, such as SiO₂, as the partition wall 52. The sidewall part 71 may be formed simultaneously with the partition wall 52. That is, for example, a LTO film is formed by a PCVD method or the like so as to entirely cover the pixel unit 100 and the peripheral unit 101B. Thereafter, the LTO film is selectively etched to form the partition wall 52 at a predetermined position of the pixel unit 100, and at the same time, the sidewall part 71 is formed at the grooves V1 and V2 and the step section SS of the peripheral unit 101B.

In general, in the vicinity of a portion where a steep wall surface having an angle close to vertical and a horizontal surface intersect, a void is likely to be formed in a gap with a film covering the steep wall surface. Specifically, a void is likely to be formed between the protection film 59 covering the sidewall surface of the groove V1 and the black filter 56 covering the protection film 59. Similarly, a void is likely to be formed between the protection film 59 covering the side wall surface of the step section SS and the lens layer 54 covering the protection film 59. Furthermore, a void is likely to be formed between the protection film 59 covering the sidewall surface of the groove V2 and the lens layer 54 covering the protection film 59. Therefore, it is possible to suppress the generation of these voids by providing the sidewall part 71, as in the peripheral unit 101B illustrated in FIG. 7B. As a result, the solid-state imaging apparatus 1B is structurally stabilized. Therefore, it is possible to effectively prevent the occurrence of cracks due to a change in temperature environment or due to aging degradation, and thus it is possible to further improve the reliability.

### (Third Modification Example of First Embodiment)

FIG. 7C illustrates a vertical cross-sectional configuration of the pixel unit 100 and a peripheral unit 101C of a solid-state imaging apparatus 1C according to a third modification example (Modification Example 1-3) of the first embodiment. FIG. 7D illustrates a vertical cross-sectional configuration of the peripheral unit 101C. In this modification example, a low-refractive index layer 52A is provided on the peripheral unit 101C. The low-refractive index layer 52A is provided so as to entirely cover the protection film 59 in the peripheral unit 101C. For example, at least portions of the grooves V1 and V2 are filled with the low-refractive index layers 52A. The low-refractive index layer 52A has a refractive index lower than that of the color filters 53. The low-refractive index layer 52A includes the same material, such as SiO₂, as the partition wall 52, for example. The low-refractive index layer 52A may be formed simultaneously with the partition wall 52. That is, for example, a LTO film is formed by a low-temperature PCVD method or the like so as to entirely cover the pixel unit 100 and the peripheral unit 101C. Thereafter, the LTO film is selectively etched to form the partition wall 52 at a predetermined position of the pixel unit 100, and at the same time, to form the low-refractive index layers 52A on the peripheral unit 101C. The black filter 56 is provided to cover a part of the low-refractive index layers 52A, for example. In the solid-state imaging apparatus 1C, the protection film 59 is entirely covered with the low-refractive index layer 52A. Therefore, the protection film 59 is not damaged by dry etching, and moisture and hydrogen are less likely to enter the color filter 53. That is, it is possible to further improve the sealing performance.

### 2. Second Embodiment

In the first embodiment, the partition wall 52 is obtained by patterning the LTO film formed by a low-temperature PCVD method. Such a LTO film may be formed at a relatively low temperature lower than or equal to 150° C., for example, and thus it is possible to prevent the organic film in the organic photoelectric conversion unit 20 from being thermally modified in the manufacturing process. However, since the LTO film includes moisture and hydrogen, the sealing film 51 is provided to prevent the moisture and hydrogen from entering the organic photoelectric conversion unit 20. Further, the sealing film 51 is prevented from being damaged in, for example, the manufacturing process by providing the protection film 59.

In contrast, in the present embodiment, the partition wall 52 is formed using a sputtered film. The sputtering film constituting the partition wall 52 includes a material, such as SiO₂, having a refractive index lower than that of the color filter 53. Since the sputtered film such as a SiO₂ film contains little water or hydrogen, the sealing film 51 makes it possible to sufficiently prevent the moisture and hydrogen from entering the organic photoelectric conversion unit 20 even if the protection film 59 is not provided as in the first embodiment. The SiO₂ formed by the sputtering method has, for example, a density of about 2.24 g/cm³, for example. The configuration of the solid-state imaging apparatus of the present embodiment is the same as the configuration of the solid-state imaging apparatus 1 of the first embodiment except that the partition wall 52 is a sputtered film formed by a sputtering method.

In the present embodiment, a nitrogen concentration and a carbon concentration of the partition wall 52 are each less than or equal to 1%. For example, in a CVD method, SiO₂ is obtained by radically oxidizing silane (SiH₄) as a raw material. The reaction at this time may be simply represented as follows.

SiH₄+N₂O→SiO₂

SiH₄+CO₂→SiO₂

Accordingly, nitrogen atoms or carbon atoms caused by radical N₂O or radical CO₂ are included in the SiO₂ formed by the CVD method. Actually, nitrogen atoms or carbon atoms having a concentration greater than 1% are detected even in the SiO₂ film formed by the CVD method at a temperature of about 400° C. Therefore, when SiO₂ is formed by a low-temperature PCVD method that forms a film at a lower temperature, the reaction is weakened, and therefore, it is considered that more nitrogen atoms and carbon atoms are included. Therefore, it is estimated that the partition wall 52 having a nitrogen concentration and a carbon concentration that are each less than or equal to 1% is formed of a sputtered film.

The method of manufacturing the solid-state imaging apparatus of the present embodiment includes forming the organic photoelectric conversion unit 20, forming the plurality of partition walls 52 standing on the organic photoelectric conversion unit 20 by a sputtering method, and forming a color filter between the plurality of partition walls 52. The nitrogen atom and the carbon atom included in the partition wall 52 formed of the sputtered film are each less than or equal to 1%.

Also in the solid-state imaging apparatus of the present embodiment, it is possible to suppress the entry of hydrogen into the semiconductor layer 21 and the entry of moisture into the organic photoelectric conversion layer 22. As a result, it is possible to maintain the operation performance of the organic photoelectric conversion unit 20 and to improve the reliability.

### 3. Third Embodiment

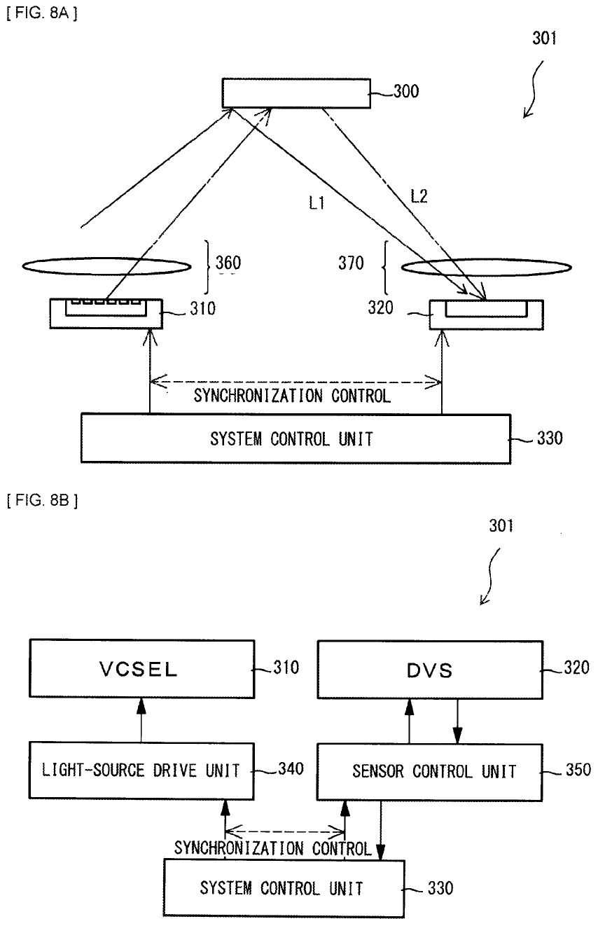

FIG. 8A is a schematic diagram illustrating an example of an overall configuration of a light detection system 301 according to a third embodiment of the present disclosure. FIG. 8B is a schematic diagram illustrating an example of a circuit configuration of the light detection system 301. The light detection system 301 includes a light emitting device 310 as a light source unit that emits light L2, and a light detecting device 320 as a light receiving unit that includes a photoelectric converter. The above-described solid-state imaging apparatus 1 may be used as the light detecting device 320. The light detection system 301 may further include a system control unit 330, a light source driving unit 340, a sensor control unit 350, a light-source-side optical system 360, and a camera-side optical system 370.

The light detecting device 320 is configured to detect light L1 and light L2. The light L1 is external ambient light reflected by a subject (subject to be measured) 300 (FIG. 8A). The light L2 is light emitted by the light emitting device 310 and then reflected by the subject 300. The light L1 is, for example, visible light, and the light L2 is, for example, infrared light. The light L1 is detectable by an organic photoelectric conversion unit in the light detecting device 320, and the light L2 is detectable by a photoelectric conversion unit in the light detecting device 320. Image data of the subject 300 may be acquired from the light L1, and distance data between the subject 300 and the light detection system 301 may be acquired from the light L2. The light detection system 301 may be mounted on, for example, electronic equipment such as a smartphone or a mobile body such as a car. The light emitting device 310 may include, for example, a semiconductor laser, a surface-emitting semiconductor laser, or a vertical-cavity surface-emitting laser (VCSEL). The light L2 emitted from the light emitting device 310 may be detected by the light detecting device 320 using, for example but not limited thereto, an iTOF method. In the iTOF method, the photoelectric conversion unit is configured to measure the distance to the subject 300 based on, for example, optical time-of-flight (TOF). The light L2 emitted from the light emitting device 310 may be detected by the light detecting device 320 using, for example, a structured light method or a stereo vision method. For example, in the structured light system, the distance between the light detection system 301 and the subject 300 may be measured by projecting light of a predetermined pattern onto the subject 300 and analyzing the degree of pattern distortion. Further, in the stereo vision system, for example, the distance between the light detection system 301 and the subject may be measured by acquiring two or more images of the subject 300 viewed from two or more different viewpoints using two or more cameras. It is to be noted that the light emitting device 310 and the light detecting device 320 may be synchronously controlled by the system control unit 330.

### 4. Exemplary Application to Electronic Equipment

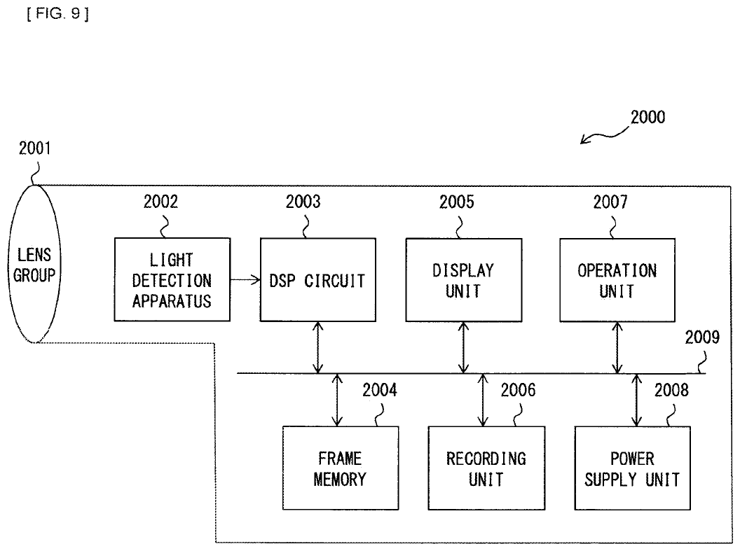

FIG. 9 is a block diagram illustrating a configuration example of electronic equipment 2000 to which the present technology is applied. The electronic equipment 2000 has a function as a camera, for example.

The electronic equipment 2000 includes an optical unit 2001 including a lens group or the like, a light detection device 2002 to which the above-described solid-state imaging apparatus 1 or the like (hereinafter, referred to as the solid-state imaging apparatus 1 and the like) is applied, and a digital signal processor (DSP) circuit 2003 that is a camera signal processing circuit. The electronic equipment 2000 further includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are coupled to each other via a bus line 2009.

The optical unit 2001 takes in incident light (image light) from the subject and forms an image on an imaging surface of the light detection device 2002. The light detection device 2002 converts the amount of incident light focused on the imaging surface by the optical unit 2001 into an electric signal on a pixel-by-pixel basis, and outputs the electric signal as a pixel signal.

The display unit 2005 includes, for example, a panel-type display device such as a liquid crystal panel or an organic EL panel, and displays a moving image or a still image captured by the light detection device 2002. The recording unit 2006 records the moving image or the still image captured by light detection device 2002 in a recording medium such as a hard disk or a semiconductor memory.

The operation unit 2007 issues an operation command for various functions of the electronic equipment 2000 in response to an operation by the user. The power supply unit 2008 appropriately supplies various types of power to be used as the operation power of the DSP circuit 2003, the frame memory 2004, the display unit 2005, the recording unit 2006, and the operation unit 2007 to these supply targets.

As described above, favorable images are expected to be obtained by using the above-described solid-state imaging apparatus 1 or the like as the light detection device 2002.

### 5. Application Example to In-Vivo Information Acquisition System

The technology according to the present disclosure (the present technology) is applicable to various products. For example, the technology according to the present disclosure may be applied to an endoscopic surgery system.

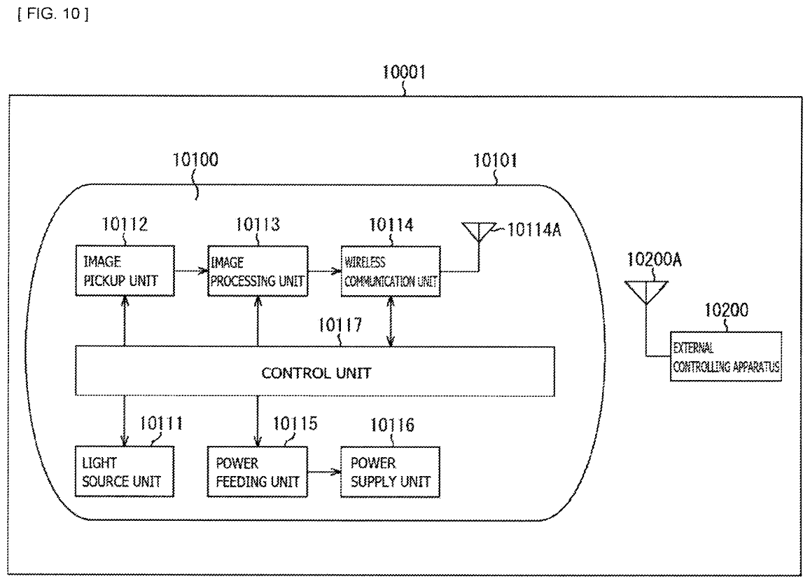

FIG. 10 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 10, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The example of the in-vivo information acquisition system to which the technology according to the present disclosure is applicable has been described above. The technology according to the present disclosure may be applied to, for example, the image pickup unit 10112 of the configuration described above. This achieves a small-size device with high image detection accuracy.

### 6. Application Example to Endoscopic Surgery System

The technology according to the present disclosure (the present technology) is applicable to various products. For example, the technology according to the present disclosure may be applied to an endoscopic surgery system.

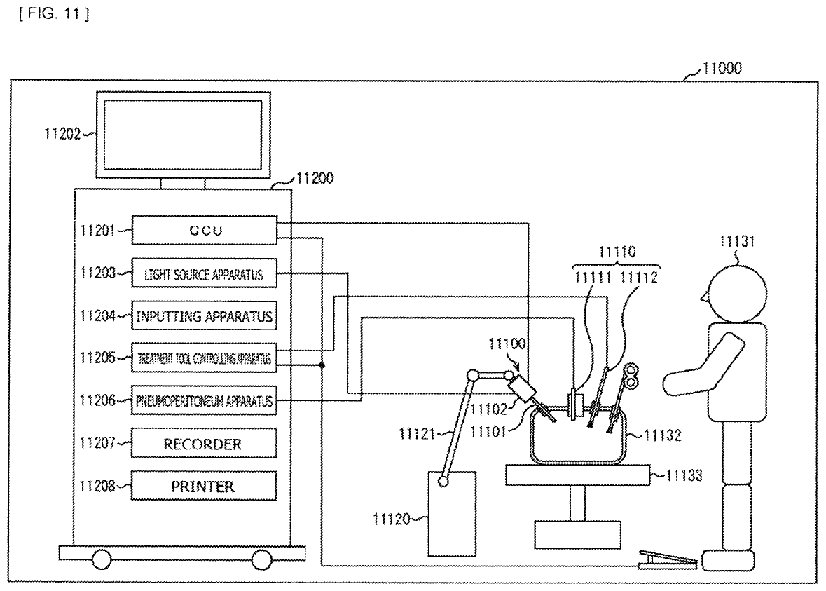

FIG. 11 is a view depicting an example of a schematic configuration of an endoscopic surgery system to which the technology according to an embodiment of the present disclosure (present technology) can be applied.

In FIG. 11, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

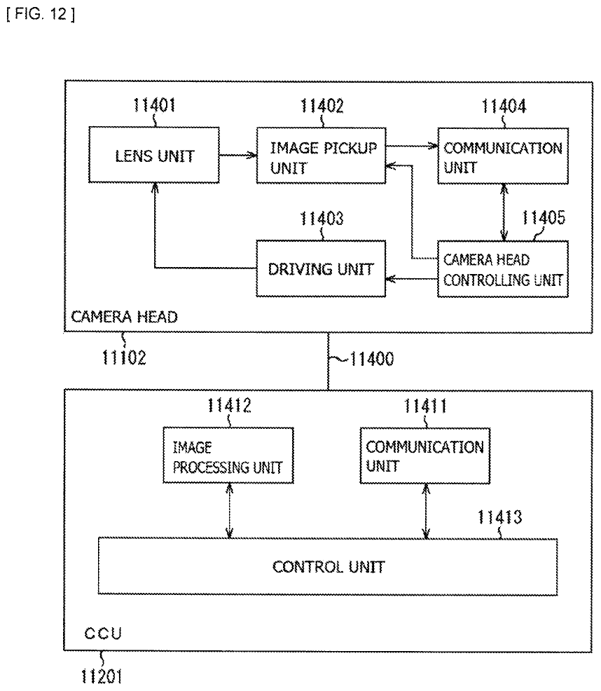

FIG. 12 is a block diagram depicting an example of a functional configuration of the camera head 11102 and the CCU 11201 depicted in FIG. 11.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure is applicable has been described above. The technology according to the present disclosure may be applied to, for example, the image pickup unit 11402 of the camera head 11102 of the configuration described above. By applying the technology according to the present disclosure to the image pickup unit 10402, clearer surgical site images can be obtained. This improves viewability of a surgical site for a surgeon.

It is to be noted that, although an endoscopic surgery system is exemplified here, the technology according to the present disclosure may be applied to other systems such as a microscopic surgery system, for example.

### 7. Application Example to Mobile Body

The technology according to the present disclosure (the present technology) is applicable to various products. For example, the technology according to the present disclosure (the present technology) may be achieved in the form of an apparatus to be mounted on a mobile body of any kind. Examples of the mobile body may include an automobile, an electric vehicle, a hybrid electric vehicle, a motorcycle, a bicycle, a personal mobility device, an airplane, a drone, a vessel, and a robot.

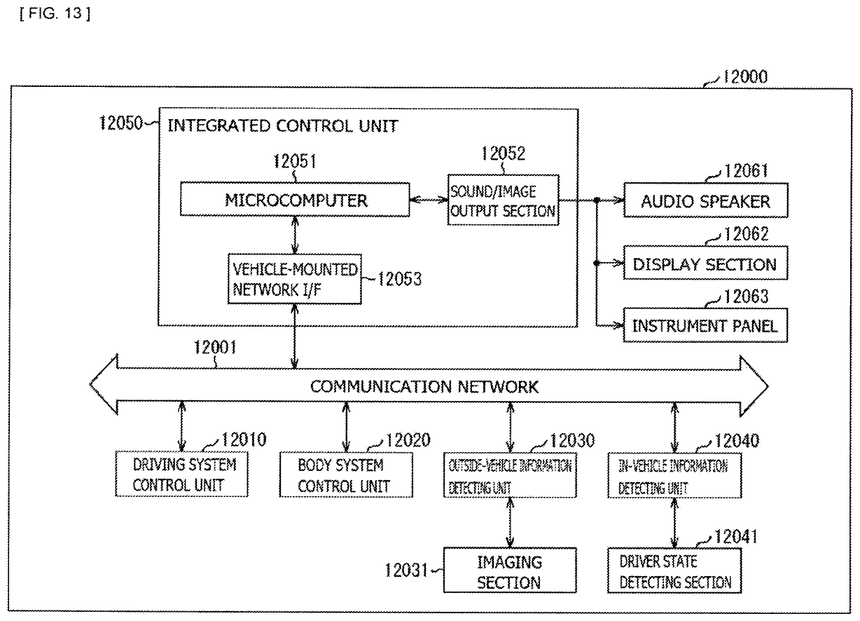

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12030 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

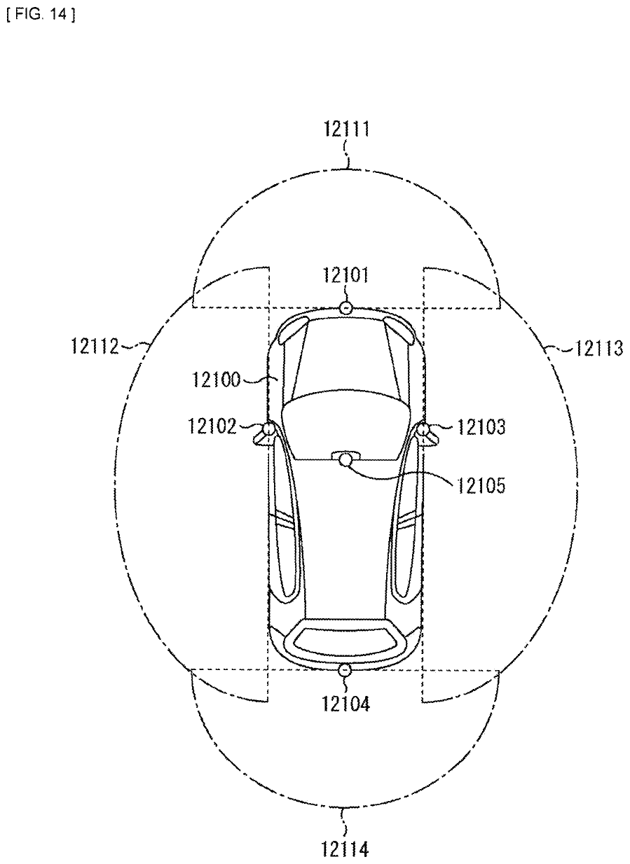

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure is applicable has been described above. The technology according to the present disclosure may be applied to, for example, the imaging section 12031 of the configuration described above. By applying the technology according to the present disclosure to the imaging section 12031, more visible captured image can be obtained. This reduces the fatigue of a driver.

### 8. Other Modification Examples

Although the present disclosure has been described above with reference to some embodiments and modification examples, and application examples or exemplary applications thereof (hereinafter referred to as embodiments and the like), the present disclosure is not limited to the above-described embodiments and the like, and various modifications may be made. For example, the present disclosure is not limited to a backside illumination type image sensor, and is also applicable to a surface illumination type image sensor.

Further, the imaging apparatus of the present disclosure may be in the form of a module in which an imaging unit and a signal processing unit or an optical system are packaged together.

Further, in the above-described embodiments and the like, the solid-state imaging apparatus that converts the amount of incident light focused on the imaging surface via the optical lens system into an electric signal on a pixel-by-pixel basis and outputs the electric signal as a pixel signal, and the image sensor mounted thereon have been described as examples; however, the photoelectric converter of the present disclosure is not limited to such an imaging element. For example, the photoelectric converter only has to detect and receive light from a subject, generate electric charges corresponding to the amount of received light by photoelectric conversion, and accumulate the electric charges. The output signal may be a signal of image information or a signal of ranging information.

Further, in the above-described embodiments and the like, an iTOF sensor is exemplified as the photoelectric conversion unit 10 serving as the second photoelectric conversion; however, the present disclosure is not limited thereto. That is, the second photoelectric conversion unit is not limited to a photoelectric conversion unit that detects light having a wavelength in the infrared light range, and may be a photoelectric conversion unit that detects light having a wavelength in another wavelength range. In a case where the photoelectric conversion unit 10 is not an iTOF sensor, only one transfer transistor (TG) may be provided.

Further, in the above-described embodiments and the like, the imaging element in which the photoelectric conversion unit 10 including the photoelectric conversion region 12 and the organic photoelectric conversion unit 20 including the organic photoelectric conversion layer 22 are stacked with the intermediate layer 40 interposed therebetween is exemplified as the photoelectric converter of the present disclosure; however, the present disclosure is not limited thereto. For example, the photoelectric converter of the present disclosure may have a structure in which two organic photoelectric conversion regions are stacked, or may have a structure in which two inorganic photoelectric conversion regions are stacked. Further, in the above-described embodiments and the like, the photoelectric conversion unit 10 performs photoelectric conversion by mainly detecting light having a wavelength in the infrared light range, and the organic photoelectric conversion unit 20 performs photoelectric conversion by mainly detecting light having a wavelength in the visible light region; however, the photoelectric converter of the present disclosure is not limited thereto. In the photoelectric converter of the present disclosure, the wavelength range sensitive to the first photoelectric conversion unit and the second photoelectric conversion unit may be freely set.

In addition, the constituent materials of the constituent elements of the photoelectric converter of the present disclosure are not limited to the materials described in the above embodiments and the like. For example, in a case where the first photoelectric conversion unit or the second photoelectric conversion unit receives light in a visible light region and photoelectrically converts the light, the first photoelectric conversion unit or the second photoelectric conversion unit may include quantum dots.

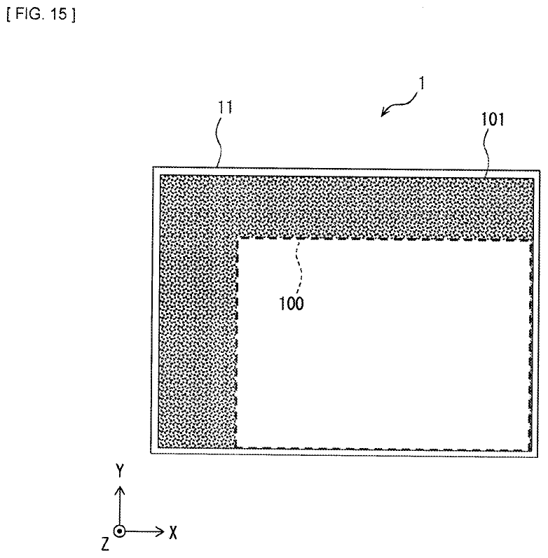

In addition, in the first embodiment and the second embodiment, the example in which the peripheral region surrounds the effective region is described; however, the light detection device of the present disclosure is not limited thereto. For example, as illustrated in FIG. 15, in the solid-state imaging apparatus 1 of the first embodiment, the peripheral unit 101 as the peripheral region faces two sides of the pixel unit 100 as the effective region.

According to an embodiment of the present disclosure, the partition wall is located in a gap between the color filters of the multiple pixels, and has a refractive index lower than that of the color filter. Therefore, it is possible to prevent the light incident on the color filter from leaking from the color filter to the surroundings.

It is to be noted that the effects described herein are mere examples. The present disclosure is thus not limited to the description and other effects may be obtained. Further, the present technology may have the following configurations.

(1) A light detection device including:
arrays of multiple pixels, the multiple pixels each including a color filter, a first photoelectric conversion layer, and an oxide semiconductor, the first photoelectric conversion layer detecting light in a first wavelength range having transmitted through the color filter and performing photoelectric conversion to generate an electric charge, the oxide semiconductor being configured to store the electric charge; and
a partition wall located in a gap between the color filters of the multiple pixels, the partition wall having a refractive index lower than that of the color filter.

(2) The light detection device according to (1), in which the partition wall is a silicon oxide film.

(3) The light detection device according to (2), in which the partition wall includes a low temperature oxide (LTO).

(4) The light detection device according to (2), further including a sealing film between the color filter and the first photoelectric conversion layer and between the color filter and the oxide semiconductor, the sealing film having a moisture transmittance lower than that of the color filter.

(5) The light detection device according to (4), in which the sealing film includes one or more of AlO, SiN, SiON, and TiO.

(6) The light detection device according to (5), further including a protection film 51 between the color filter and the sealing film, the protection film 51 having an etching resistance with respect to an alkaline developer higher than that of the sealing film.

(7) The light detection device according to (6), in which the protection film includes one or both of TiO₂ and SiN.

(8) The light detection device according to (6), further including:
an effective region in which the multiple pixels are provided; and
a peripheral region adjacent to the effective region, in which
the protection film is formed in both of the effective region and the peripheral region.

(9) The light detection device according to any one of (1) to (8), in which the partition wall includes an insulating material.

(10) The light detection device according to (9), in which the partition wall has a nitrogen concentration and a carbon concentration each of which is less than or equal to 1%.

(11) The light detection device according to (9) or (10), in which the partition wall is a sputtering film.

(12) The light detection device according to any one of (1) to (11), in which the first photoelectric conversion layer is located between the oxide semiconductor and the color filter.

(13) The light detection device according to any one of (1) to (12), in which the multiple pixels each further include a second photoelectric conversion layer provided overlapping with the first photoelectric conversion layer, the second photoelectric conversion layer detecting light in a second wavelength range having transmitted through the first photoelectric conversion layer and performing photoelectric conversion.

(14) The light detection device according to (13), further including an optical filter between the first photoelectric conversion layer and the second photoelectric conversion layer, the optical filter transmitting the light in the second wavelength range more easily than the light in the first wavelength range.

(15) A method of manufacturing a light detection device, the method including:
forming a photoelectric conversion unit that includes a photoelectric conversion layer and an oxide semiconductor, the photoelectric conversion layer receiving light and performing photoelectric conversion to generate an electric charge, the oxide semiconductor being configured to store the electric charge;
forming a plurality of partition walls standing on the photoelectric conversion unit by a sputtering method; and
forming a color filter between the plurality of the partition walls.

(16) Electronic equipment including:
an optical unit;
a signal processing unit; and
a light detection device, in which
the light detection device includes
   arrays of multiple pixels, the multiple pixels each including a color filter, a photoelectric conversion layer, and an oxide semiconductor, the photoelectric conversion layer detecting light in a first wavelength range having transmitted through the color filter, and performing photoelectric conversion to generate an electric charge, the oxide semiconductor being configured to store the electric charge; and
   a partition wall located in a gap between the color filters of the multiple pixels, the partition wall having a refractive index lower than that of the color filter.

(17) A mobile body including:
a light emitting device that emits irradiation light; and
a light detection device including
   arrays of multiple pixels, the multiple pixels each including a color filter, a photoelectric conversion layer, and an oxide semiconductor, the photoelectric conversion layer detecting light in a first wavelength range having transmitted through the color filter, and performing photoelectric conversion to generate an electric charge, the oxide semiconductor being configured to store the electric charge; and
   a partition wall located in a gap between the color filters of the multiple pixels, the partition wall having a refractive index lower than that of the color filter.

The present application claims the benefit of Japanese Priority Patent Application JP2021-171955 filed with the Japan Patent Office on Oct. 20, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light detection device comprising:
arrays of multiple pixels, the multiple pixels each including a color filter, a first photoelectric conversion layer, and an oxide semiconductor, the first photoelectric conversion layer detecting light in a first wavelength range having transmitted through the color filter, and performing photoelectric conversion to generate an electric charge, the oxide semiconductor being configured to store the electric charge; and
a partition wall located in a gap between the color filters of the multiple pixels, the partition wall having a refractive index lower than that of the color filter.

2. The light detection device according to claim 1, wherein the partition wall is a silicon oxide film.

3. The light detection device according to claim 2, wherein the partition wall includes a low temperature oxide (LTO).

4. The light detection device according to claim 2, further comprising a sealing film between the color filter and the first photoelectric conversion layer and between the color filter and the oxide semiconductor, the sealing film having a moisture transmittance lower than that of the color filter.

5. The light detection device according to claim 4, wherein the sealing film includes one or more of AlO, SiN, SiON, and TiO.

6. The light detection device according to claim 5, further comprising a protection film between the color filter and the sealing film, the protection film having an etching resistance with respect to an alkaline developer higher than that of the sealing film.

7. The light detection device according to claim 6, wherein the protection film includes one or both of TiO₂ and SiN.

8. The light detection device according to claim 6, further comprising:
an effective region in which the multiple pixels are provided; and
a peripheral region adjacent to the effective region, wherein
the protection film is formed in both of the effective region and the peripheral region.

9. The light detection device according to claim 1, wherein the partition wall includes an insulating material.

10. The light detection device according to claim 9, wherein the partition wall has a nitrogen concentration and a carbon concentration each of which is less than or equal to 1%.

11. The light detection device according to claim 9, wherein the partition wall is a sputtering film.

12. The light detection device according to claim 1, wherein the first photoelectric conversion layer is located between the oxide semiconductor and the color filter.

13. The light detection device according to claim 1, wherein the multiple pixels each further include a second photoelectric conversion layer provided overlapping with the first photoelectric conversion layer, the second photoelectric conversion layer detecting light in a second wavelength range having transmitted through the first photoelectric conversion layer and performing photoelectric conversion.

14. The light detection device according to claim 13, further comprising an optical filter between the first photoelectric conversion layer and the second photoelectric conversion layer, the optical filter transmitting the light in the second wavelength range more easily than the light in the first wavelength range.

15. A method of manufacturing a light detection device, the method comprising:
forming a photoelectric conversion unit that includes a photoelectric conversion layer and an oxide semiconductor, the photoelectric conversion layer receiving light and performing photoelectric conversion to generate an electric charge, the oxide semiconductor being configured to store the electric charge;
forming a plurality of partition walls standing on the photoelectric conversion unit by a sputtering method; and
forming a color filter between the plurality of the partition walls.

16. Electronic equipment comprising:
an optical unit;
a signal processing unit; and
a light detection device, wherein
the light detection device includes
arrays of multiple pixels, the multiple pixels each including a color filter, a photoelectric conversion layer, and an oxide semiconductor, the photoelectric conversion layer detecting light in a first wavelength range having transmitted through the color filter, and performing photoelectric conversion to generate an electric charge, the oxide semiconductor being configured to store the electric charge; and
a partition wall located in a gap between the color filters of the multiple pixels, the partition wall having a refractive index lower than that of the color filter.

17. A mobile body comprising:
a light emitting device that emits irradiation light; and
a light detection device including
arrays of multiple pixels, the multiple pixels each including a color filter, a photoelectric conversion layer, and an oxide semiconductor, the photoelectric conversion layer detecting light in a first wavelength range having transmitted through the color filter, and performing photoelectric conversion to generate an electric charge, the oxide semiconductor being configured to store the electric charge; and
a partition wall located in a gap between the color filters of the multiple pixels, the partition wall having a refractive index lower than that of the color filter.
